(19) United States
(12) Patent Application Publication
(10) Pub. No.: US 2026/0040534 A1
(43) Pub. Date: Feb. 5, 2026

(54) MEMORY DEVICES WITH BURIED DIGIT LINES

(71) Applicant: Micron Technology, Inc., Boise, IL (US)

(72) Inventors: Russell Allen Benson, Boise, ID (US); Vinay Nair, Boise, ID (US); Jaydip Guha, Boise, ID (US); Si-Woo Lee, Saratoge, CA (US); Anthony J. Kango, Boise, ID (US); Sheng Wei Yang, Boise, ID (US)

(21) Appl. No.: 19/284,442

(22) Filed: Jul. 29, 2025

Related U.S. Application Data
(60) Provisional application No. 63/677,872, filed on Jul. 31, 2024.

(51) Int. Cl. H10B 12/00

(52) U.S. Cl. CPC H10B 12/482; H10B 12/02

(57) ABSTRACT

A variety of applications can include an apparatus having a memory device, where the memory device includes a digit line coupled to a access transistor of a memory device. The digit line can be at least partially buried below a top surface of substrate cell contacts to the access transistor. The top surface of the substrate cell contacts can be located at the surface of the substrate. The digit line can be formed in a separation of cell contacts first formation process flow or a digit line first formation process.

### PRIORITY APPLICATION

This application claims the benefit of priority to U.S. Provisional Application Ser. No. 63/677,872, filed Jul. 31, 2024, which is incorporated herein by reference in its entirety.

### FIELD OF THE DISCLOSURE

Embodiments of the disclosure relate generally to electronic devices and systems, and more specifically, to memory devices, components of memory devices, and formation thereof.

### BACKGROUND

Memory devices are typically provided as internal, semiconductor, integrated circuits in computers or other electronic devices. There are many different types of memory, including volatile and non-volatile memory. Volatile memory requires power to maintain its data, and includes random-access memory (RAM), dynamic random-access memory (DRAM), static RAM (SRAM), or synchronous dynamic random-access memory (SDRAM), among others. Non-volatile memory can retain stored data when not powered, and includes flash memory, read-only memory (ROM), electrically erasable programmable ROM (EEPROM), erasable programmable ROM (EPROM), resistance variable memory, such as phase-change random-access memory (PCRAM), resistive random-access memory (RRAM), magnetoresistive random-access memory (MRAM), or three-dimensional (3D) XPoint™ memory, among others. Properties of memory devices can be improved by enhancements to the design and fabrication of components of the memory devices.

### BRIEF DESCRIPTION OF THE DRAWINGS

The drawings, which are not necessarily drawn to scale, illustrate generally, by way of example, but not by way of limitation, various embodiments discussed in the present document.

FIG. 1 is a representation of an example structure including components of a dynamic random-access memory device having a digit line at least partially buried below a top surface of substrate cell contacts to an access transistor and to a capacitor of a memory cell of a memory array of the dynamic random-access memory device, in accordance with various embodiments.

FIG. 2 is a representation of a 6F² architecture of an array of memory cells, in accordance with various embodiments.

FIG. 3 is a flow diagram of features of an example method 300 of forming a memory device, in accordance with various embodiments.

FIG. 4 is a flow diagram of features of an example method of forming a memory device, in accordance with various embodiments.

FIGS. 5-15 illustrate an example process of forming at least partial buried digit lines in a separation of cell contacts first formation process flow, in accordance with various embodiments.

FIGS. 16-30 illustrate example methods of digit line contact punch that can be used in formation of least partial digit lines in a separation of cell contacts first formation process flow and in a digit line first formation process, in accordance with various embodiments.

FIGS. 31-45 illustrate an embodiment of an example method of forming at least partial buried digit lines in a digit line first formation process flow, in accordance with various embodiments.

FIG. 46 is a schematic of an example dynamic random-access memory device that can include an architecture having at least partially buried below a top surface of substrate cell contacts to an access transistor and to a capacitor of a memory cell of a memory array of the dynamic random-access memory device, in accordance with various embodiments.

FIG. 47 is a block diagram illustrating an example of a machine upon which one or more embodiments of one or more memory components may be implemented, in accordance with various embodiments.

### DETAILED DESCRIPTION

The following detailed description refers to the accompanying drawings that show, by way of illustration, various embodiments that can be implemented. These embodiments are described in sufficient detail to enable those of ordinary skill in the art to practice these and other embodiments. Other embodiments may be utilized, and structural, logical, mechanical, and electrical changes may be made to these embodiments. The term “horizontal” as used in this application is defined as a plane parallel to a conventional plane or surface of a wafer or substrate, regardless of the orientation of the wafer or substrate. The term “vertical” refers to a direction perpendicular to the horizontal as defined above. Various features can have a vertical component to the direction of their structure. The various embodiments are not necessarily mutually exclusive, as some embodiments can be combined with one or more other embodiments to form new embodiments. The following detailed description is, therefore, not to be taken in a limiting sense.

With scaling of memory array dimensions, lower capacitance of digit lines (DLs) that transfer data, for example bit lines, can become critical for read/write timing associated with memory array access and for signal margin of sense amplifiers of the memory device. As DRAM devices scale, for example, resistance of a DL (digit resistance) and capacitance associate with the digital line (digit capacitance) limit scaling of the critical dimension (CD) of metal DLs and total spacer thickness. However, a landing area for a contact to a memory cell continues to scale faster, which can lead to efforts to resolve interlayer dielectric (ILD) to recover area associated with the contact.

In various embodiments, designs and process flows can address issues associated with DLs and scaling of memory devices. Such process flows can include multiple flow variations for burying DLs to memory cells of a memory array. One variation can include forming DLs first in a direction followed by separating cell contacts to the memory cells in another direction. Another variation can include first separating cell contacts to the memory cells along a direction followed by forming DLs in another direction. Cell contacts in a DRAM device can include a DL contact to the drain of an access transistor of a memory cell, with a contact cap on and contacting the DL contact, and substrate cell contacts to the memory cell, with contact caps on the substrate cell contacts. A DL contact can be referred to herein as a bit contact or a bitcon and a substrate cell contact can be referred to herein as a CCON. The separation of cell contacts can include separation of cell contacts that include metal in contact caps to the cell contacts.

In a DL first formation, DLs are fully buried below the top surface of the CCONs, where the top surface of the CCONs can be a surface of the substrate in which the transistors of the memory cells of the memory array are formed. The CCONs can be silicon CCONs. The silicon CCONs can extend downward as pillars from the substrate surface (top surface) to access transistors of memory cells of a DRAM device, where each access transistor is coupled to a capacitor. The capacitors can be positioned above the level of the top surface of the CCONs.

In a separation of cell contact first formation, the DLs can be formed after cell contact separation, with an adjustable DL depth, that is, the DLs can be formed having a depth, relative to the top surface of the CCONs, ranging from a partially buried DL to fully buried DL. The capability to form the DLs with a selected height of burial can reduce burden on access line (WL) depth and shallow trench isolation (STI) trench depth. A WL, such as a word line for example, can be coupled to the gates of one or more access transistors. The capability to form the DLs to a selected height of burial can reduce DL to WL parasitic capacitance but may increase CCON to DL capacitance. This process flow may include a more challenging DL trench etch; for example, etching alternating a nickel liner and a stacks to the cell contacts.

The multiple flow variations for burying DLs to memory cells of a memory array can include variations to the starting stack to the cell contacts. A stack to a cell contact provides a contact cap to a cell contact. The variations can include a full stack and a partial stack. A full starting stack to the cell contacts can include polysilicon, a silicide, a metal, and a nitride cap. The formation of the full starting stack can include an 100% planar stack deposition with no voids or seams. Optionally, the formation of the full starting stack can include no silicide formation within the cell contact. A high temperature rapid thermal processing (RTP) post metal deposition can limit silicide material formation. RTP can be conducted at or above 1000° C. for a short period, which can be a few seconds. A partial starting stack to the cell contacts can include polysilicon and a nitride cap. A partial starting stack may be implemented with extra processing post formation of complementary metal-oxide-semiconductor (CMOS) devices in the periphery to the memory array to expose cell contacts and perform cobalt silicide (CoSi_{X}) formation. The polysilicon can still maintain a low number of voids, which can provide for best CoSi_{X} formation for single bit (SBIT) fail.

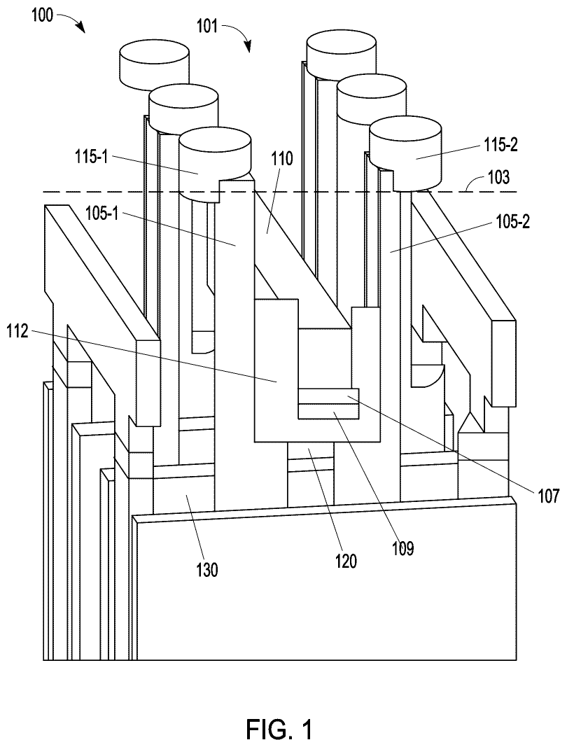

FIG. 1 is a representation of an embodiment of an example structure 100 including components of a DRAM device having a DL 110 at least partially buried below a top surface 103 of CCONs 105-1 and 105-2, which are coupled to an access transistor and a capacitor of a memory cell of a memory array of the DRAM device. The memory cells can be arranged, but are not limited to, a 6F² architecture. The access transistors of the array of memory cells can be located in a substrate below surface 103 and the capacitors can be located above surface 103. The access transistors can be thin film transistors (TFTs). Top surface 103 can be a top surface of the substrate. The substrate for the memory cells can be, but is not limited to, a silicon substrate. DL 110 can be positioned in a region cut to form the DL 110 as a damascene DL. A damascene method can include etching line features and via features in a dielectric and then filling those features with metal. The damascene method can include performing a pattern operation prior to etching and also filing the features with barrier metals for the metal. A dual-damascene process can include patterning vias and trenches, in such that metal formation fills the vias and trenches at the same time.

A dielectric spacer 112 can be positioned about DL 110 isolating DL 110 from CCONs 105-1 and 105-2 and other CCONs in the structure. In structure 100, DL 110 is located completely below top surface 103. In other embodiments, a portion of DL 110 can be located above top surface 103 and another portion of DL 110 can be located below top surface 103. With the portion of DL 110 located below top surface 103, DL 110 is recessed having a recess depth to top surface 103 of CCONs 105-1 and 105-2, the recess depth can provide an optimization of parasitic DL capacitance versus access device performance.

Though the access transistor is not shown, the access transistor can be coupled to a WL 130 and to DL 110. DL 110 can be coupled to the access transistor by a DL contact 120 via a polysilicon region 109 and a barrier metal region 107. Polysilicon region 109 and barrier metal region 107 provides a contact cap to DL contact 120. Barrier metal region 107 is part of the coupling of the DL 110 to the DL contact 120 to the access transistor, where polysilicon region 109 is positioned between barrier metal region 107 and DL contact 120. Barrier metal region 107 can include, but is not limited to, one or more of titanium (Ti), titanium nitride (TiN), tungsten nitride (WN), tungsten silicide (WSi_{X}), or tungsten silicide nitride (WSi_{X}N). DL 110 can include, but is not limited to, one or more of W, TiW, or molybdenum (Mo). Dielectric spacer 112 can include, but is not limited to, one or more of silicon oxycarbide (SiOC), silicon dioxide (SiO₂), and silicon nitride (Si₃N₄). WL 130 can include, but is not limited to, polysilicon.

Contact caps can be provided to CCONs such as CCONs 105-1 and 105-2. These contact caps can be structured similar to the contact cap to DL 110, including a barrier metal on a polysilicon region that is on and contacting the CCON. The CCONs can be silicon-based structures. For example, such contact caps can include polysilicon regions including polysilicon region 115-1 on and contacting CCON 105-1 and polysilicon region 115-2 on and contacting CCON 105-1 and 105-2 1. The CCONs can be recessed with the polysilicon region of a CCON contact cap overlapping a corresponding silicon CCON. The contact caps can couple CCONs to a redistribution layer (RDL).

Example dimensions of the components of structure 100 can include, but are not limited to, DL 110 having a thickness in the range of about 10 nm to about 20 nm in the vertical direction and a CD in the horizontal direction of about 6 nm to 10 nm. Barrier metal region 107 can have, but is not limited to, a thickness in the range of about 2 nm to about 8 nm. Polysilicon region 109 can have, but is not limited to, a thickness in the range of about 0 nm to about 5 nm. By 0 nm, it is meant that structure 100 can be implemented without polysilicon region 109. Dielectric spacer 112 can have, but is not limited to, a spacer thickness in the range of about 4 nm to about 8 nm. The recess for contact caps to the CCONs, such as CCONs 105-1 and 105-2, can have a depth, but is not limited to, in a range of about 0 nm to 20 nm. By 0 nm, it is meant that structure 100 can be implemented without a recess for contact caps to the CCONs.

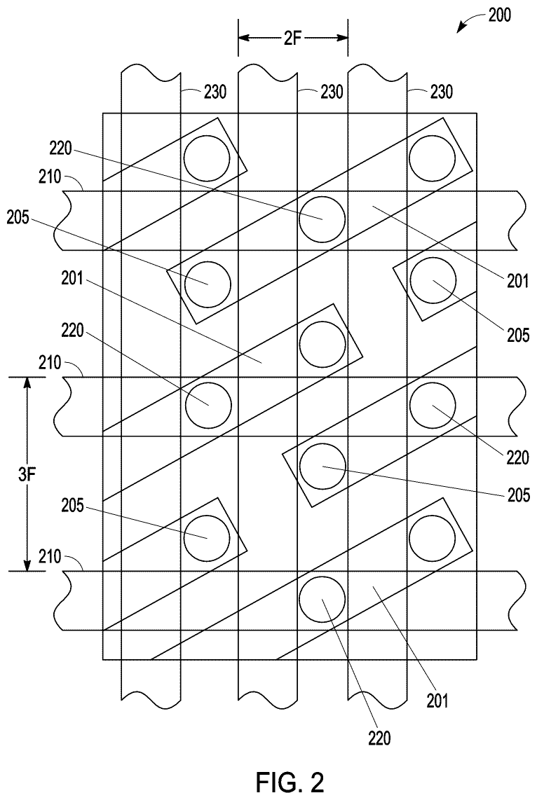

FIG. 2 is a representation of an embodiment of an example memory device 200 that includes memory cells array in a 6F² architecture with DLs at least partially buried below a top surface of CCONs to transistors of memory cells. Structure 100 provides an example of a memory device having buried DLs that can be used in memory device 200. Memory device 200 includes active areas 201 coupled to CCONs 205, where CCONs 205 can be positioned in pairs on opposite sides of a DL contact 220. DL contacts 220 are coupled to DLs 210 that are patterned in one directions, with WLs patterned in another direction. In memory device 200, pitch of WLs is 2F and pitch of DLs is 3F, where F is the feature size of the process technology. Memory cell sizes are measured using an nF² formula where ‘n’ is a constant derived from the cell design. In 6F² memory cell configuration of memory device 200, the WL pitch is 2F and the DL pitch is 2F, resulting in the 6F² area of the unit cell for the 6F² architecture.

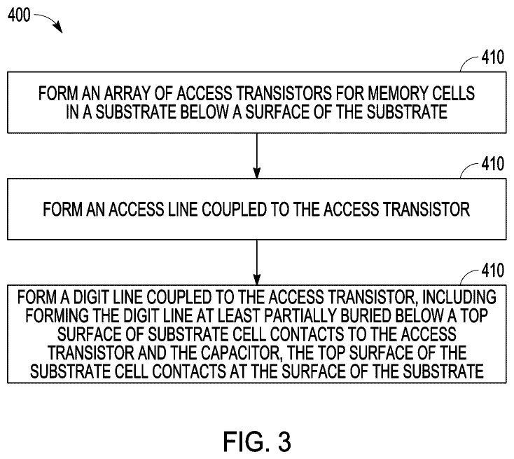

FIG. 3 is a flow diagram of features of an embodiment of a method 300 of forming a memory device. The memory device can be a DRAM device. Method 300 can be used to form structure 100 of FIG. 1. At 310, an array of access transistors for memory cells is formed in a substrate below a surface of the substrate. An access transistor of the array is being coupled to a capacitor forming a memory cell. The formation of the access transistors of the array can be formed in a common process at the same time. The array of memory cells can be formed with the memory cells arranged in a 6F² architecture. At 320, a WL is formed coupled to the access transistor. At 330, a DL coupled to the access transistor is formed, including forming the DL at least partially buried below a top surface of substrate cell contacts to the access transistor and the capacitor, where the top surface of the substrate cell contacts are at the surface of the substrate.

Variations of method 300 or methods similar to method 300 can include a number of different embodiments that may be combined depending on the application of such methods or the architecture or process flow of an integrated circuit for which such methods are implemented. Such methods can include completely burying the DL below the top surface of the substrate cell contacts.

Variations can include, in a first processing direction, forming the substrate cell contacts and a DL contact to the access transistor electrically separated from each other. In a second processing direction, after forming the substrate cell contacts and the DL contact electrically separated from each other, the DL can be formed coupled to the DL contact in a damascene trench.

Variations can include, in a first processing direction, forming the DL in a damascene trench and coupled to a DL contact to the access transistor. In a second processing direction, after forming the DL coupled to a DL contact, the substrate cell contacts and the DL contact can be formed electrically separated from each other.

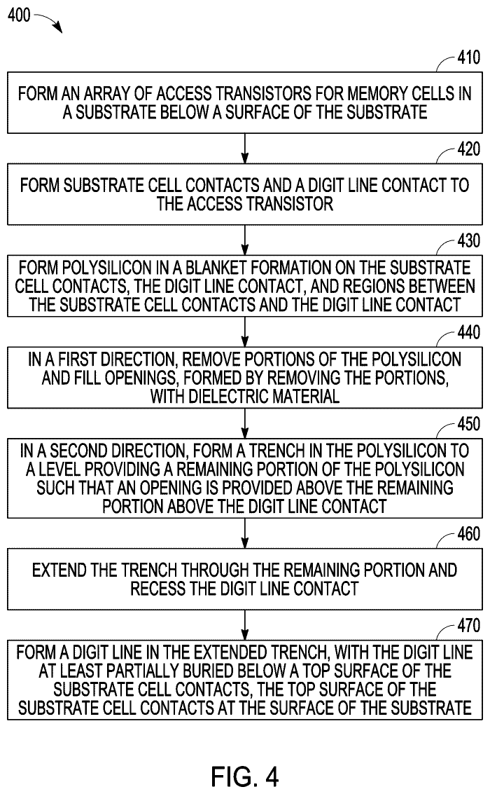

FIG. 4 is a flow diagram of features of an embodiment of a method 400 of forming a memory device. The memory device can be a DRAM device. Method 400 can be used to form structure 100 of FIG. 1. At 410, an array of access transistors for memory cells is formed in a substrate below a surface of the substrate. An access transistor of the array is being coupled to a capacitor forming a memory cell. The formation of the access transistors of the array can be formed in a common process at the same time. The array of memory cells can be formed with the memory cells arranged in a 6F² architecture. At 420 substrate cell contacts and a DL contact to the access transistor are formed.

At 430, polysilicon is formed in a blank formation on the substrate cell contacts, the DL contact, and regions between the substrate cell contacts and the DL contact. At 440, in a first direction, portions of the polysilicon are removed and openings, formed by removing the portions, are filled with dielectric material. At 450, in a second direction, a trench is formed in the polysilicon to a level, providing a remaining portion of the polysilicon such that an opening is provided above the remaining portion above the DL contact.

At 460, the trench is extended through the remaining portion and the DL contact is recessed. At 470, a DL is formed in the extended trench, with the DL at least partially buried below a top surface of the substrate cell contacts, where the top surface of the substrate cell contacts are at the surface of the substrate.

Variations of method 400 or methods similar to method 400 can include a number of different embodiments that may be combined depending on the application of such methods or the architecture or process flow of an integrated circuit for which such methods are implemented. Such methods can include forming, above the polysilicon, material for contact caps to the substrate cell contacts and performing processing in the two directions. In the first direction, portions of the material for contact caps are removed when removing portions of the polysilicon, electrically separating contact caps to the substrate cell contacts from each other. In the second direction, the trench is formed through the material for contact caps when forming the trench in the polysilicon.

Variations of method 400 or methods similar to method 400 can include forming material for contact caps by forming a metal region on a metal barrier contacting the polysilicon. Variations can include forming a protective liner on walls of the trench, extending the trench through the remaining portion, and recessing the DL contact. Variations can include adjusting a recess depth of the DL from the top surface of the substrate cell contacts to provide a desired status of parasitic DL capacitance versus access device performance.

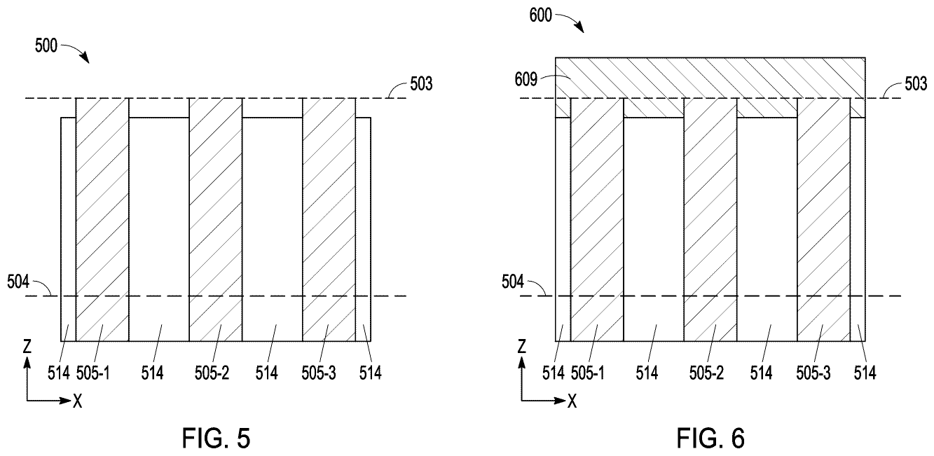

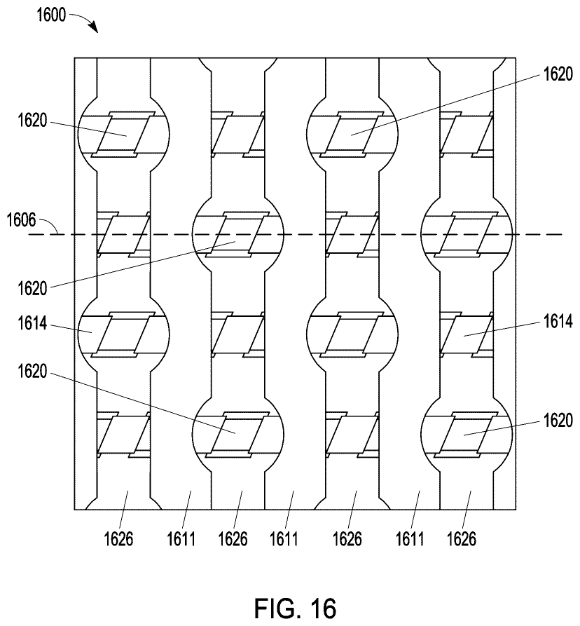

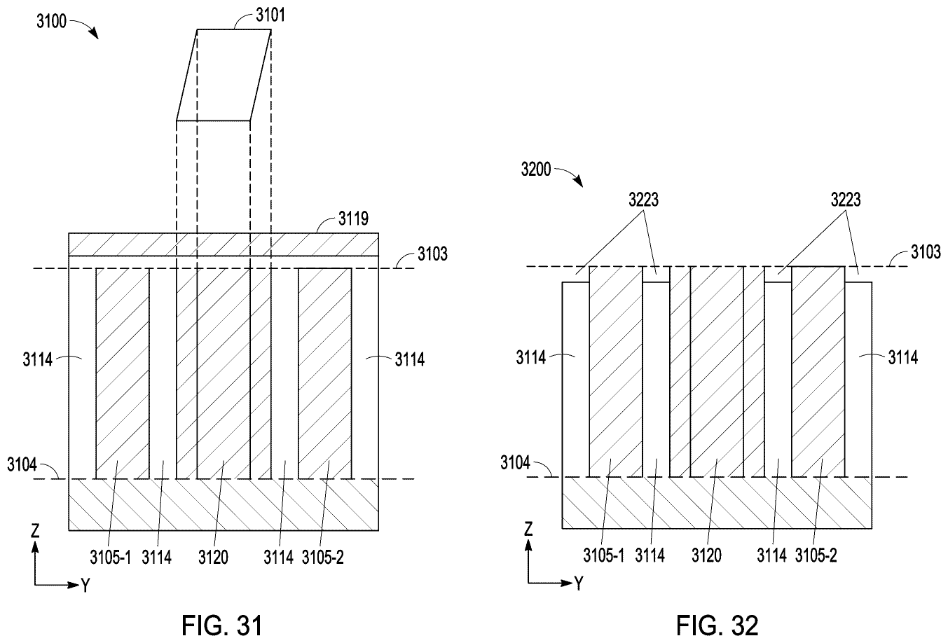

FIGS. 5-45 illustrate process flows of embodiments of example methods of forming at least partial buried DLs for memory cells of a memory array of a memory device. FIGS. 5-15 illustrate an embodiment of an example method of forming at least partial buried DLs in a separation of cell contacts first formation process flow. FIGS. 16-30 illustrate embodiments of example methods of DL contact punch that can be used in formation of least partial DLs in a separation of cell contacts first formation process flow and in a DL first formation process. A punch is a process implemented to form an opening in dielectric material. The DL contact punch provides an opening in which a DL can be formed. FIGS. 31-45 illustrate an embodiment of an example method of forming at least partial buried DLs in a DL first formation process flow.

FIG. 5 illustrates a cross-sectional view of a structure 500, in a separation of cell contacts first process flow, as an intermediate structure in forming a memory device. The memory device can be a DRAM device. CCONs 505-1, 505-2, and 505-3 have been formed in a dielectric 514, where CCON 505-1, CCON 505-2, and CCON 505-3 can provide coupling to a capacitor that defines a memory cell along with the access transistor. The cross-sectional view is along a first direction, for example a x-direction, with CCON 505-1, CCON 505-2, and CCON 505-3 extending in the z-direction. For ease of presentation of formation of a buried DL, the access transistor is not shown though a top level 504 of a WL to the access transistor is represented. The process involved with FIGS. 5-15 can be applied to the DLs to memory cells of an array of the memory device. Dielectric 514 can be part of an ILD, where dielectric 514 has resulted from removal of a portion of the ILD, where the removal includes a recess around top portions of CCON 505-1, CCON 505-2, and CCON 505-3. The top portions of CCON 505-1, CCON 505-2, and CCON 505-3 have a top surface at CCON surface 503. The recess depth can be adjusted to improve interfaces of CCON 505-1, CCON 505-2, and CCON 505-3 to contact caps. The adjustment can be an increase of the recess depth. CCON 505-1, CCON 505-2, and CCON 505-3 can be formed as Si columns such as, but not limited to, Si pillars. CCONs 505-1, 505-2, and 505-3 can be processed to have contact caps, where each contact cap can include a polysilicon region on and contacting the respective one of CCONs 505-1, 505-2, and 505-3. Dielectric 514 can be, but is not limited to, silicon oxide.

FIG. 6 illustrates a cross-sectional view of a structure 600, in a separation of cell contacts first process flow, after processing structure 500 of FIG. 5 along the x-direction. A polysilicon 609 has been formed on the surfaces of structure 500. The formation on the surfaces can be a blanket deposition. The formation can include a RTP application without voids and seams. The RTP application can be performed before CMOS device processing in the periphery to the memory array.

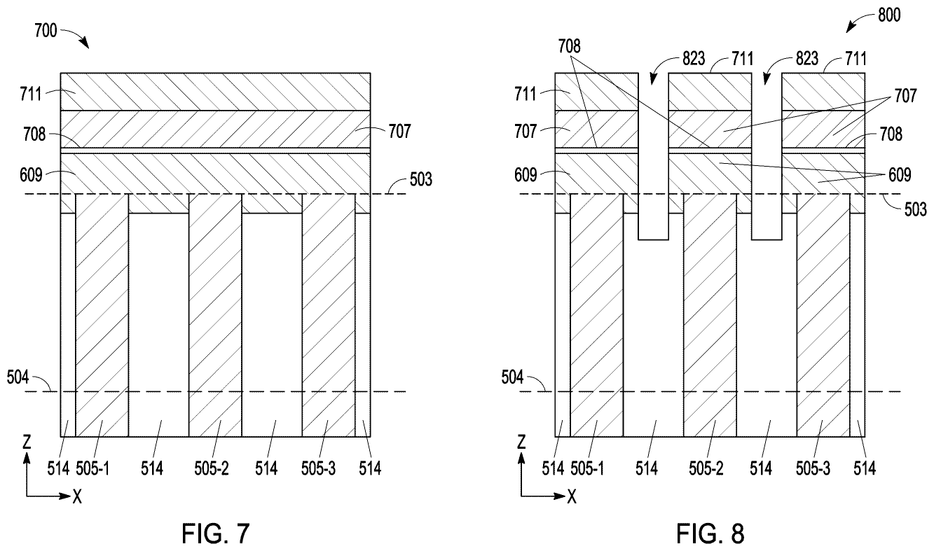

FIG. 7 illustrates a cross-sectional view of a structure 700, in a separation of cell contacts first process flow, after processing structure 600 of FIG. 6 along the x-direction. Material has been formed on the surface of polysilicon 609 of structure 600. The material formation can be a deposition of a metal and a barrier region between the metal and polysilicon 609. The barrier region can include, but is not limited to, a barrier metal such as a metal silicide. In the example shown, a metal silicide 708 has been formed on and contacting polysilicon 609 and a metal 707 has been formed on metal silicide 708. A dielectric 711 has been formed on metal 707. Metal 707 can include, but is not limited to, W. Dielectric 711 can be a nitride such as, but not limited to a silicon nitride (SiN_{X}). Optionally, the metal formation can be formed at a different phase of the memory device formation. The metal formation can be integrated with formation of a CMOS device in the periphery to the memory array and the barrier region can be formed with a common silicide to the CMOS device. A blanket barrier metal and metal formation to a CCON should improve CCON resistance as opposed to silicide within a contact region to a CCON. In the formation of structure 700, CCON 505-1, CCON 505-2, and CCON 505-3 have been electrically connected together.

FIG. 8 illustrates a cross-sectional view of a structure 800, in a separation of cell contacts first process flow, after processing structure 700 of FIG. 7 along the x-direction. Conductive connecting of CCON 505-1, CCON 505-2, and CCON 505-3 has been separated by a CCON cut that can be accomplished by a non-selective etch without a self-aligned contact etch. Openings 823 have been formed by the separation. In addition, a contact cap has been formed to each of CCON 505-1, CCON 505-2, and CCON 505-3 separated by openings 823. Each contact cap formed includes dielectric 711 on metal 707 on metal silicide 708 on polysilicon 609.

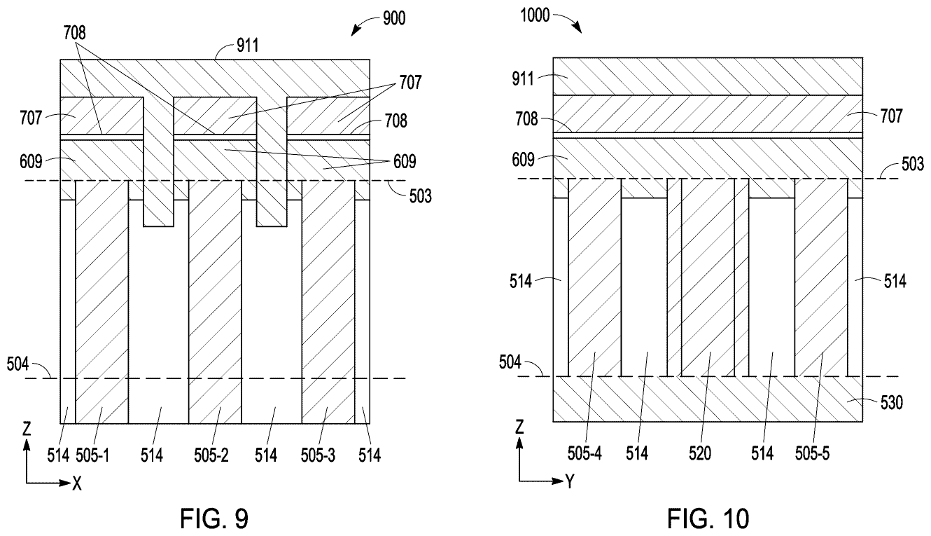

FIG. 9 illustrates a cross-sectional view of a structure 900, in a separation of cell contacts first process flow, after processing structure 800 of FIG. 8 along the x-direction. A dielectric 911 has been formed in openings 823 of structure 800. With dielectric 911 being the same material as dielectric 711, dielectric 711 and dielectric 911 form a continuous dielectric 911.

FIG. 10 illustrates a cross-sectional view of a structure 1000, in a separation of cell contacts first process flow, along the y-direction with respect to a CCON 505-4, a DL contact 520, and a CCON 505-5 that is in a direction perpendicular to the separated CCON 505-1, CCON 505-2, and CCON 505-3 of structure 900 in the x-direction process. In this cross-sectional view, a formed WL 530 is shown having top level 504.

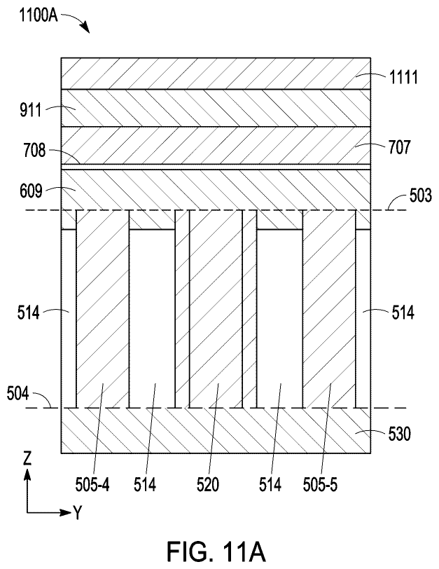

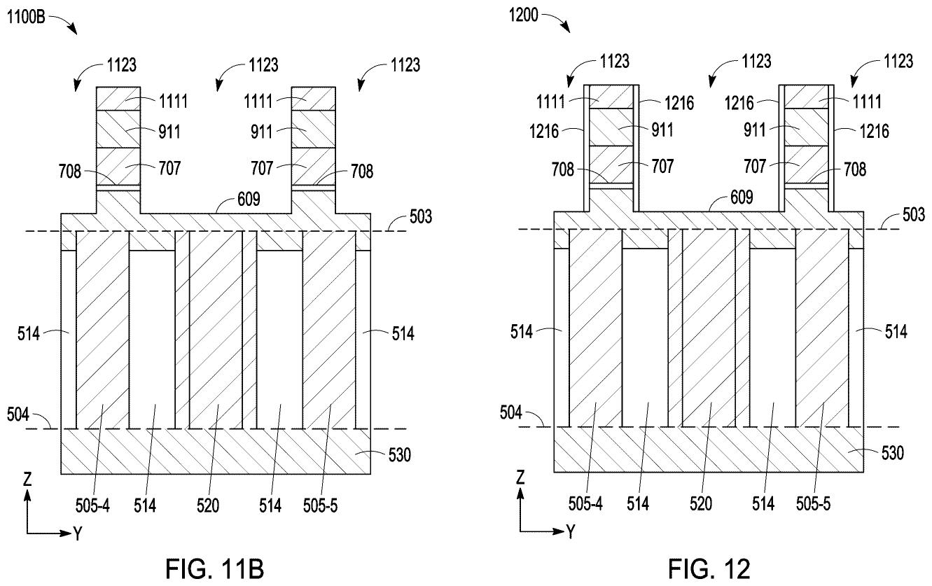

FIG. 11A illustrates across-sectional view of a structure 1100A in the y-direction, in a separation of cell contacts first process flow, after processing structure 1000 of FIG. 10. A dielectric region 1111 has been deposited before a damascene etch. Dielectric region 1111 can be a sacrificial hardmask. Dielectric region 1111 can be a spin-on zirconium oxide (ZrO_{X}) dielectric through a coat and bake process but could also be SiO₂ or one or more other possible sacrificial films. FIG. 11B illustrates a cross-sectional view of a structure 1100B in the y-direction, in a separation of cell contacts first process flow, after processing structure 1100A of FIG. 111A. A first partial etch has been performed for generating a damascene DL. Openings 123 have been formed and dielectric region 1111 has been separated by the etch.

FIG. 12 illustrates a cross-sectional view of a structure 1200 in the y-direction, in a separation of cell contacts first process flow, after processing structure 1100 of FIG. 11. A partial liner 1216 has been formed. Partial liner 1216 can be formed by a deposition of SiO_{X}C_{Y}. Other materials for partial liner 1216 that can be used include, but are not limited to, one or more of an SiO_{X}, SiN_{X}, or other dielectric nitride. Optionally, the separation of cell contacts first process flow can be performed without partial liner 1216.

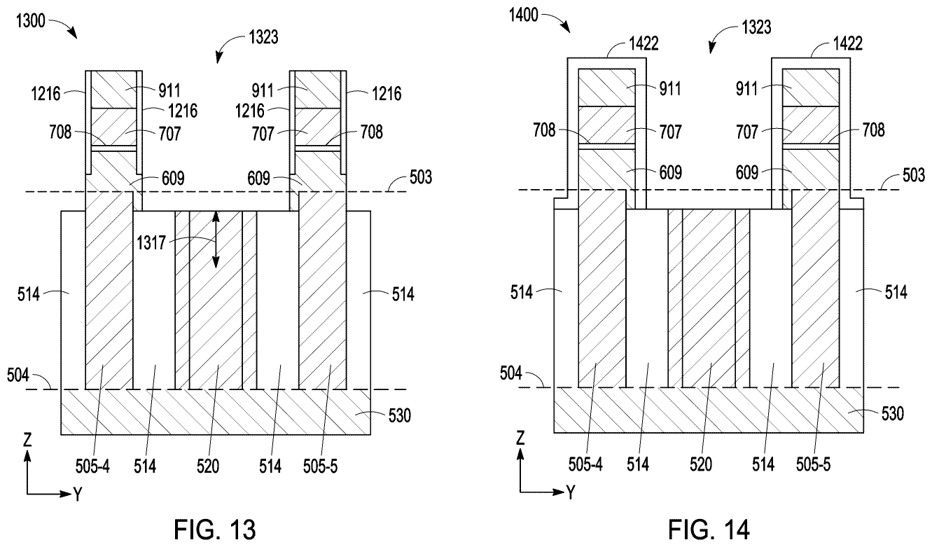

FIG. 13 illustrates a cross-sectional view of a structure 1300 in the y-direction, in a separation of cell contacts first process flow, after processing structure 1200 of FIG. 12. A final partial etch has been performed, removing dielectric region 1111 and forming a damascene trench 1323 for processing a damascene DL. Depth of damascene trench 1323 is defined by the top of DL contact 520, which can be adjusted in formation as indicated by depth 1317. Damascene trench 1323 can be shallow to increase DL to WL margin. Metal height of the DL to be formed, corresponding to depth 1317, is not restricted by CCONs 505-4 and 505-5 but can have increased DL to CCON capacitance.

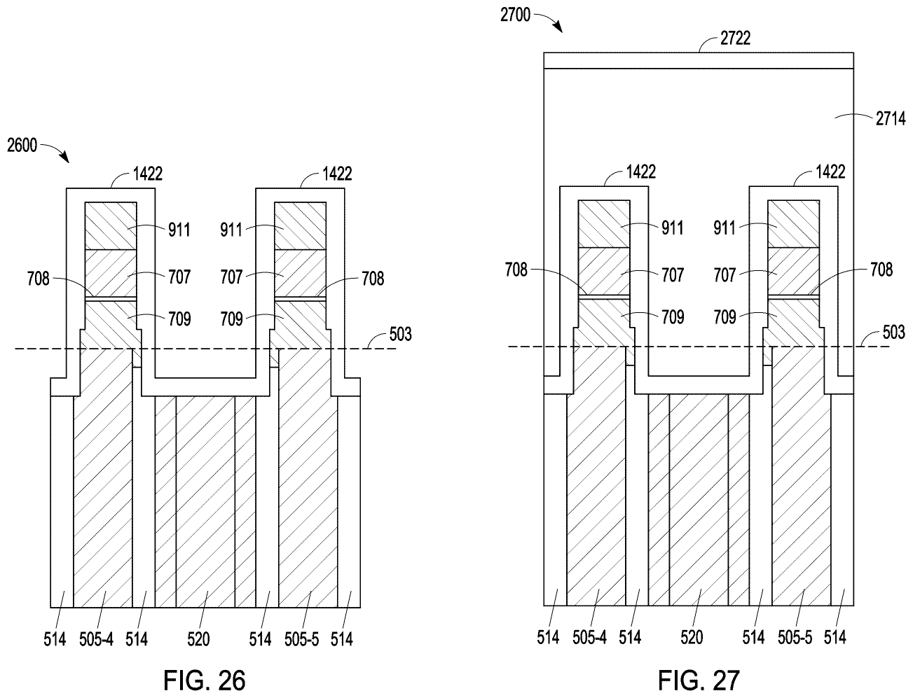

FIG. 14 illustrates a cross-sectional view of a structure 1400 in the y-direction, in a separation of cell contacts first process flow, after processing structure 1300 of FIG. 13. A DL spacer 1422 has been formed followed by a punch process. DL spacer 1422 can be, but is not limited to, SiO_{X}C_{Y}. The punch process can be accomplished in a number of methods. FIGS. 16-25 provide an example bubble flow DL contact punch and FIGS. 26-30 provide another example DL contact punch.

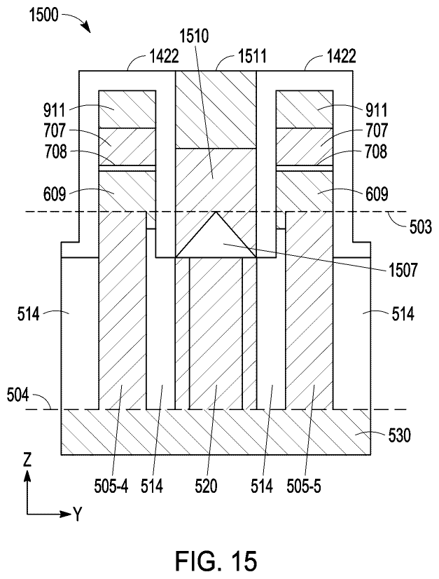

FIG. 15 illustrates a cross-sectional view of a structure 1500 in the y-direction, in a separation of cell contacts first process flow, after processing structure 1400 of FIG. 14. An epitaxial silicon 1507 has be formed on DL contact 520 and a DL 1510 has been formed on epitaxial silicon 1507. DL 1510 can be a metal with a barrier metal between the metal and epitaxial silicon 1507. A dielectric 1511 has been formed on DL 1510. Dielectric 1511 can be a dielectric nitride, such as but not limited to SiN_{X}. Though DL 1510 is shown as partially buried below CCON surface 503, DL 1510 can be totally below CCON surface 503. DL 1510 can be approximately 25 nm below CCON surface 503. Such a depth below the top of CCONs 505-4 and 505-5 can enhance a RDL output enable (OE) margin. Damascene recess to provide buried DL 1510 can be varied to maximize resistance of DL 1510 and minimize DL capacitance.

FIG. 16 illustrates a top view of a structure 1600 in a bubble flow process for a DL punch for a memory device. The procedures of FIGS. 16-25 are discussed relative to a region of multiple DL contacts 1620, which can be applied to a structure similar to structure 1400 of FIG. 14. Structure 1600 has a number of DL contacts 1620 enclosed in the plane of the top view by a dielectric 1614. Dielectric 1614 provides an ILD that isolates CCONs and DL contacts from each other. Dielectric 1614 can be, but is not limited to, SiN_{X} or SiO_{X}. A capping layer 1611 can be, but is not limited to, SiN_{X}. An ILD isolation 1626 has been provided above an underlying WL. A bubble etch pattern has been generated in which a “bubble” is formed around DL contacts 1620. ILD isolation 1626 can be, but is not limited to, SiN_{X} or SiO_{X}.

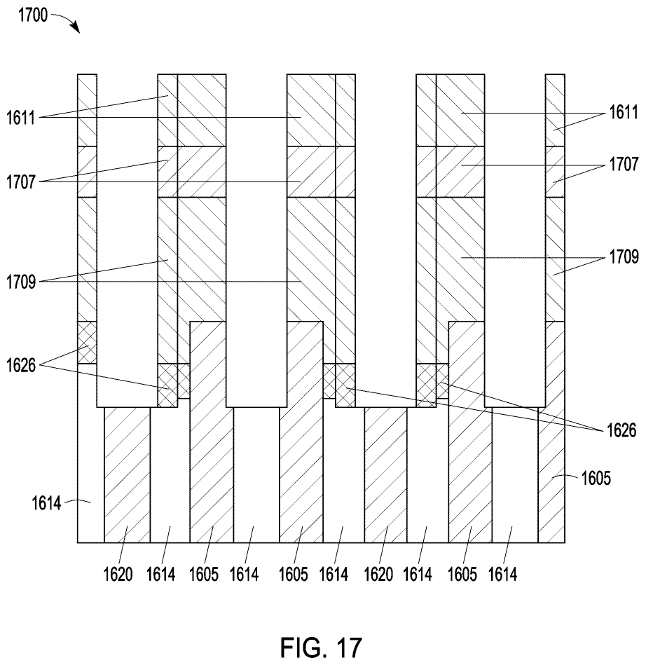

FIG. 17 illustrates a cross-sectional view of a structure 1700 corresponding to the top view of structure 1600 along line 1606 of FIG. 16. Capping layer 1611 has been formed on metal region 1707 that is on polysilicon 1709. Polysilicon 1709 is on CCONs 1605, where CCONs 1605 and DL contacts 1610 are separated from each other by dielectric 1614. A contact cap has not yet been formed on DL contacts 1610 as the bubble flow is a process in forming a damascene DL.

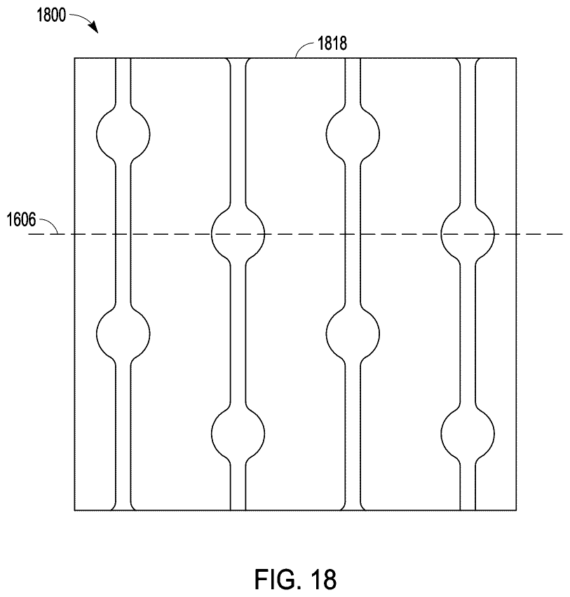

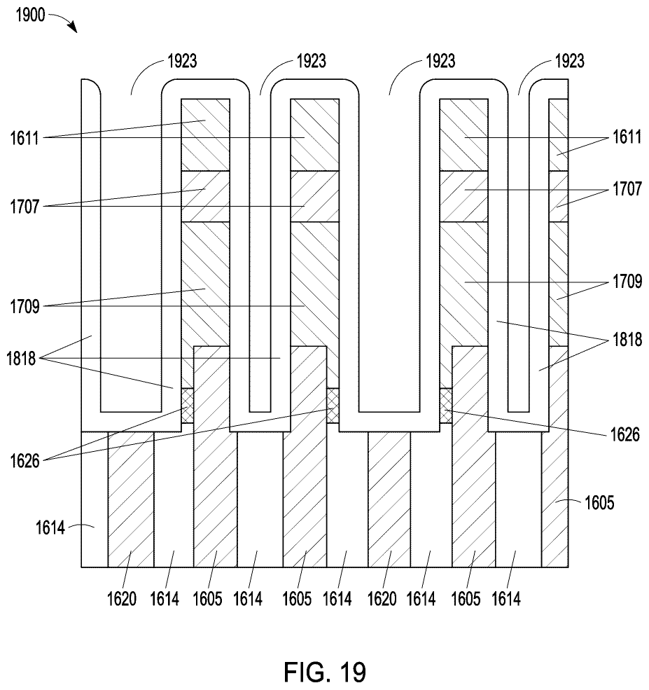

FIG. 18 illustrates a top view of a structure 1800, in a bubble flow process for a DL punch, after processing structure 1600. Dielectric 1818 has been formed on the surface of structure 1600. Dielectric 1818 can be, but is not limited to, SiO_{X}C_{Y}. FIG. 19 illustrates a cross-sectional view of a structure 1900 corresponding to the top view of structure 1800 along line 1606.

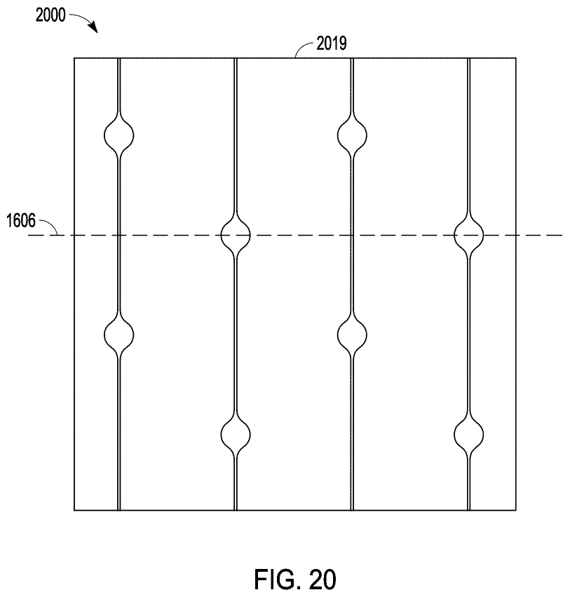

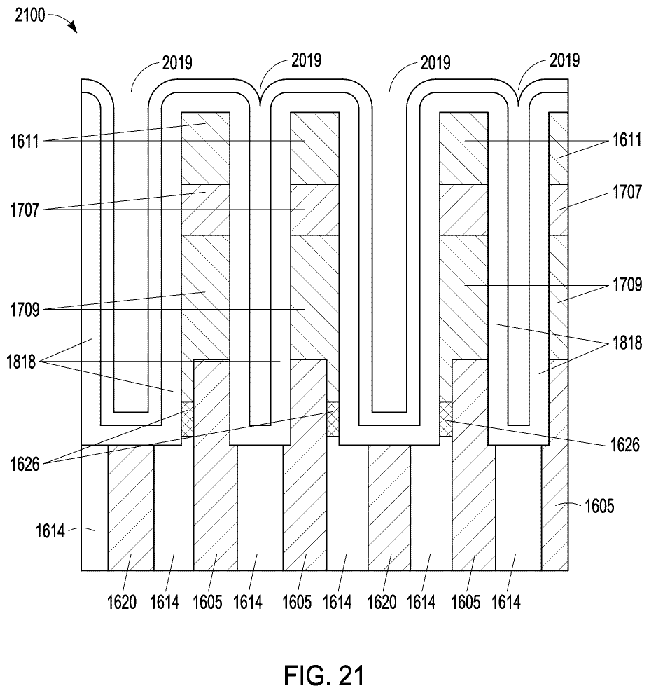

FIG. 20 illustrates a top view of a structure 2000, in a bubble flow process for an DL punch, after processing structure 1800. A sacrificial spacer 2019 had been formed. Sacrificial spacer 2019 can be, but is not limited to, an oxide. The oxide can be, but is not limited to, SiO_{X}. FIG. 21 illustrates a cross-sectional view of a structure 2100 corresponding to the top view of structure 2000 along line 1606.

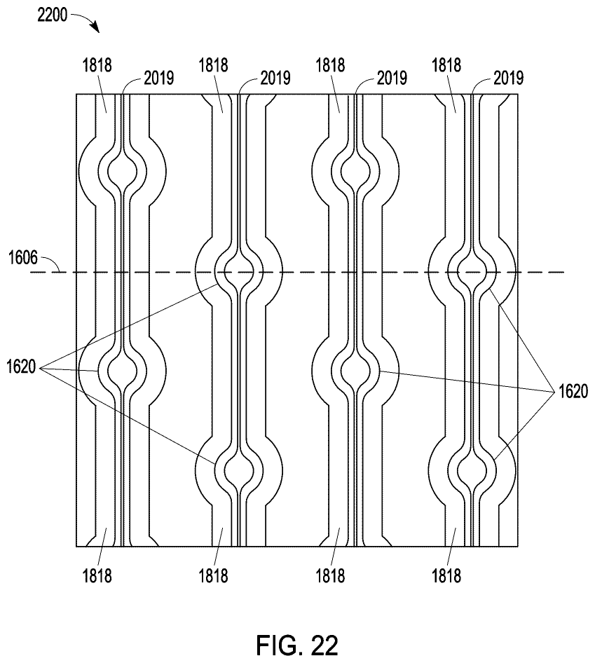

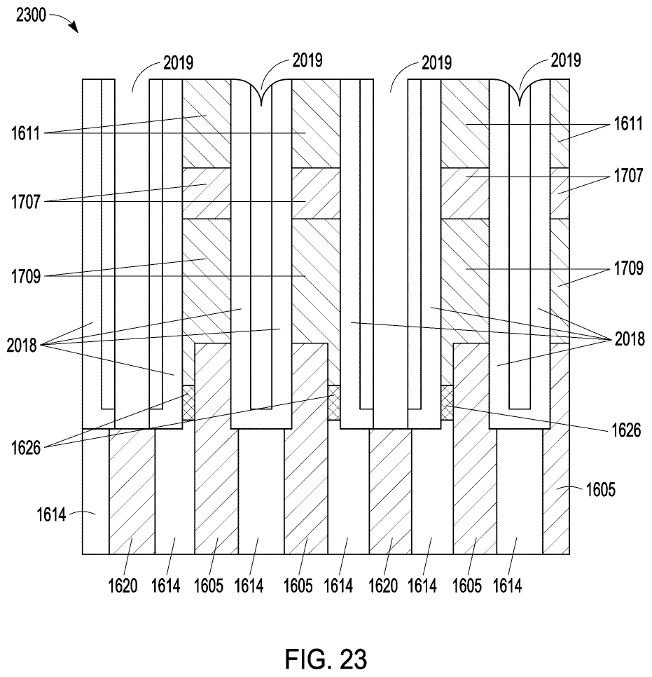

FIG. 22 illustrates a top view of a structure 2200, in a bubble flow process for an DL punch, after processing structure 2000. A punch has been performed down to DL contacts 1620. FIG. 23 illustrates a cross-sectional view of a structure 2300 corresponding to the top view of structure 2200 along line 1606.

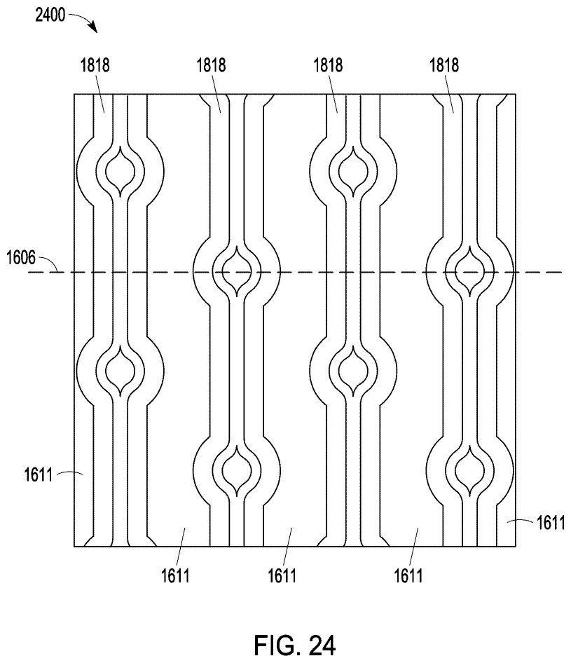

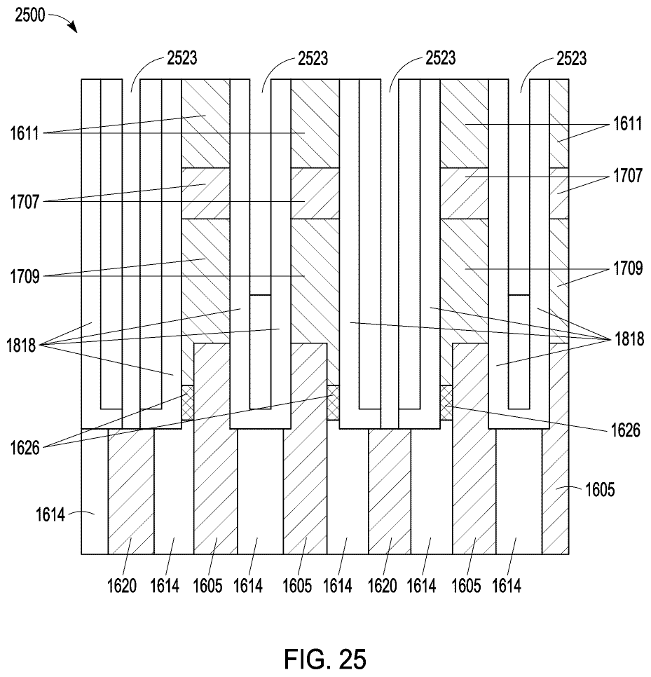

FIG. 24 illustrates a top view of a structure 2400, in a bubble flow process for an DL punch, after processing structure 2200. Sacrificial spacer 2019 has been removed. FIG. 25 illustrates a cross-sectional view of a structure 2500 corresponding to the top view of structure 2400 along line 1606.

FIG. 26 illustrates a cross-sectional view of a structure 2600 for a DL punch procedure performed on structure 1300 of FIG. 13 in a procedure resulting in structure 1400. Dielectric spacer 1422 has been formed on the surfaces of structure 1300 of FIG. 13. Dielectric spacer 1422 can be, but is not limited to, SiO_{X}C_{Y}.

FIG. 27 illustrates a cross-sectional view of a structure 2700, in a patterned punch process for DLs for a memory device, after further processing of structure 2600. An anti-reflective coating (ARC) 2714 has been formed on dielectric spacer 1422. A dielectric 2722 has been formed on ARC 2714. Dielectric 2722 can have the same composition as dielectric spacer 1422.

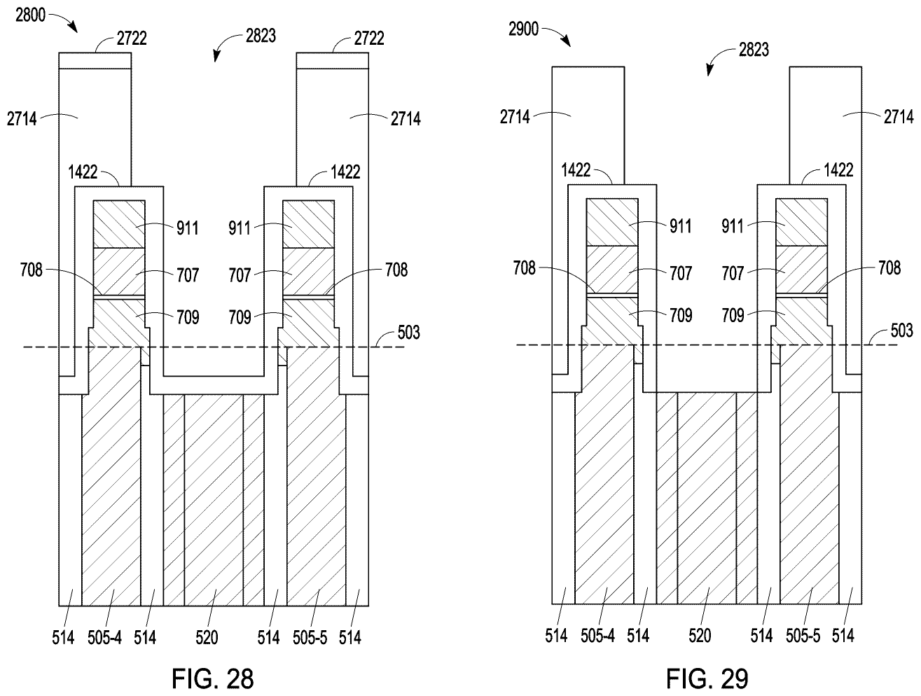

FIG. 28 illustrates a cross-sectional view of a structure 2800, in a patterned punch process, after processing structure 2700 of FIG. 27. Photolithography, a dry etch, and a cleaning has been performed, forming opening 2823. Remaining material of dielectric 2722 may be damaged.

FIG. 29 illustrates a cross-sectional view of a structure 2900, in a patterned punch process, after processing structure 2800 of FIG. 28. Remaining material of dielectric 2722 has been further removed from structure 2800, providing a clean surface of structure 2900 without dielectric 2722.

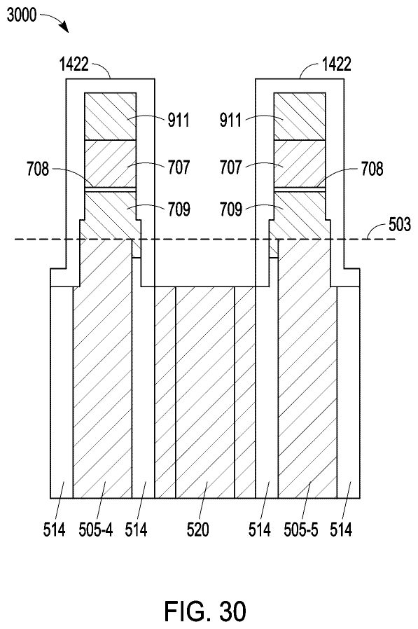

FIG. 30 illustrates a cross-sectional view of a structure 3000, in a patterned punch process, after processing structure 2900 of FIG. 29. Remaining portions of ARC 214 have been removed. Structure 3000 becomes structure 1400 of FIG. 14, for further processing of the buried DL as shown in FIG. 15.

FIG. 31 illustrates across-sectional view of a structure 3100, in a DL first formation, as an intermediate structure in forming a memory device. The memory device can be a DRAM device. CCONs 3105-1 and 3105-2 have been formed on opposite sides of DL contact 3120 in a dielectric 3114, where DL contact 3120 is coupled to an access transistor and CCON 3105-1 and CCON 3105-2 provide coupling to a capacitor that defines a memory cell along with the access transistor. Dielectric 3114 extends above the top surfaces, in the z-direction, of CCON 3105-1, CCON 3105-2, and DL contact 3120. Dielectric 3119 has been formed on dielectric 3114. The cross-sectional views are along a first direction, for example a y-direction, with CCON 3105-1, CCON 3105-2, and DL contact 3120 extending in the z-direction. View 3101 of DL contact 3120 shows an example extent of DL contact 3120 in the x-direction. For ease of presentation of formation of a buried DL, the access transistor is not shown though a top level 3104 of a WL to the access transistor is represented. The process involved with FIGS. 31-45 can be applied to the DLs to memory cells of an array of the memory device. The top portions of CCON 3105-1, CCON 3105-2, and DL contact 3120 have a top surface at CCON surface 3103. CCONs 3105-1 and 3105-2 and DL contact 3120 can be formed as Si columns such as, but not limited to, Si pillars. CCONs 3105-1 and 3105-2 and DL contact 3120 can be processed to have contact caps, where each contact cap can include a polysilicon region on and contacting the respective one of CCONs 3105-1 and 3105-2 and DL contact 3120. Dielectric 3114 can be, but is not limited to, silicon oxide. Dielectric 3119 can be, but is not limited to, a nitride. The nitride can be, but is not limited to, silicon nitride.

FIG. 32 illustrates a cross-sectional view of a structure 3200, in a DL first formation, after processing structure 3100 of FIG. 31 along the y-direction. Dielectric 3114, which can be part of an ILD, has been recessed around top portions of CCON 3105-1, CCON 3105-2, and DL contact 3120, forming recesses 3223. The recess depth can be adjusted to improve interfaces of CCON 3105-1, CCON 3105-2, and DL contact 3120 to contact caps that are to be formed. The adjustment can be an increase of the recess depth.

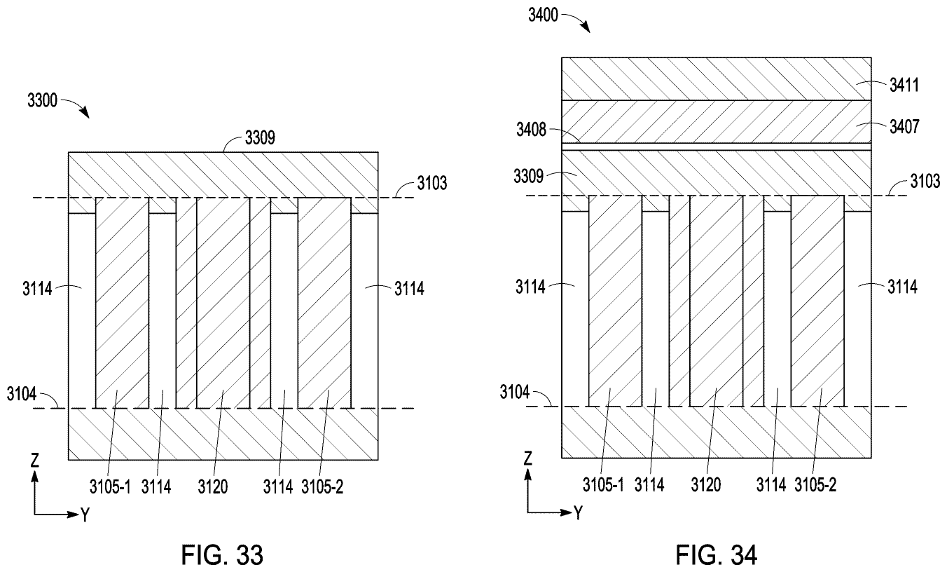

FIG. 33 illustrates a cross-sectional view of a structure 3300, in a DL first formation, after processing structure 3200 of FIG. 32 along the y-direction. A polysilicon 3309 has been formed on the surfaces of structure 500. The formation on the surfaces can be a blanket deposition. The formation can include a RTP application and without voids and seams. The RTP application can be performed before CMOS device processing in the periphery to the memory array.

FIG. 34 illustrates a cross-sectional view of a structure 3400, in a DL first formation, after processing structure 3300 of FIG. 33 along the y-direction. Material has been formed on the surface of polysilicon 3309 of structure 3300. The material formation can be a deposition of a metal and a barrier region between the metal and polysilicon 3309. The barrier region can include, but is not limited to, a barrier metal such as a metal silicide. In the example shown, a metal silicide 3408 has been formed on and contacting polysilicon 3309 and a metal 3407 has been formed on metal silicide 3408. A dielectric 3411 has been formed on metal 3407. Metal 3407 can include, but is not limited to, W. Dielectric 3411 can be a nitride such as, but not limited to a silicon nitride. Optionally, the metal formation can be formed at a different phase of the memory device formation. The metal formation can be integrated with formation of a CMOS device in the periphery to the memory array and the barrier region can be formed with a common silicide to the CMOS device. A blanket barrier metal and metal formation to a CCON should improve CCON resistance as opposed to silicide within a contact region to a CCON. In the formation of structure 3400, CCON 3105-1, CCON 3105-2, and DL contact 3120 have been electrically connected together.

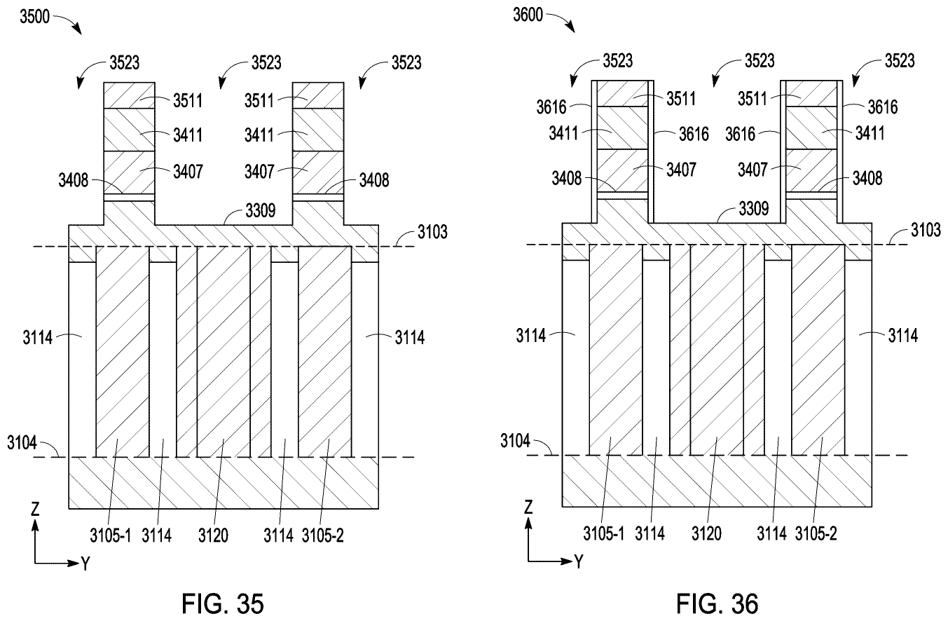

FIG. 35 illustrates a cross-sectional view of a structure 3500, in a DL first formation, after processing structure 3400 of FIG. 34 along the y-direction. A dielectric region 3511 has been formed on dielectric 3411 of structure 3400 of FIG. 34. Dielectric region 3511 can be, but is not limited to, a zirconium oxide (ZrO_{X}). A first partial etch to form a damascene DL has been performed, forming openings 3523. The partial etch can stop at polysilicon 3309 to allow a liner to be formed to encapsulate metal prior to exposing CCON 3105-1, CCON 3105-2, and DL contact 3120. In addition, a contact cap has been formed to each of CCON 3105-1, CCON 3105-2, and DL contact 3120 separated by openings 3523. Each contact cap formed includes dielectric 3411 on metal 3407 on metal silicide 3408 on polysilicon 3409.

FIG. 36 illustrates a cross-sectional view of a structure 3600, in a DL first formation, after processing structure 3500 of FIG. 35 along the y-direction. A partial liner 3616 has been formed, which can include a punch process. The partial liner 3616 can be, but is not limited to, NOx.

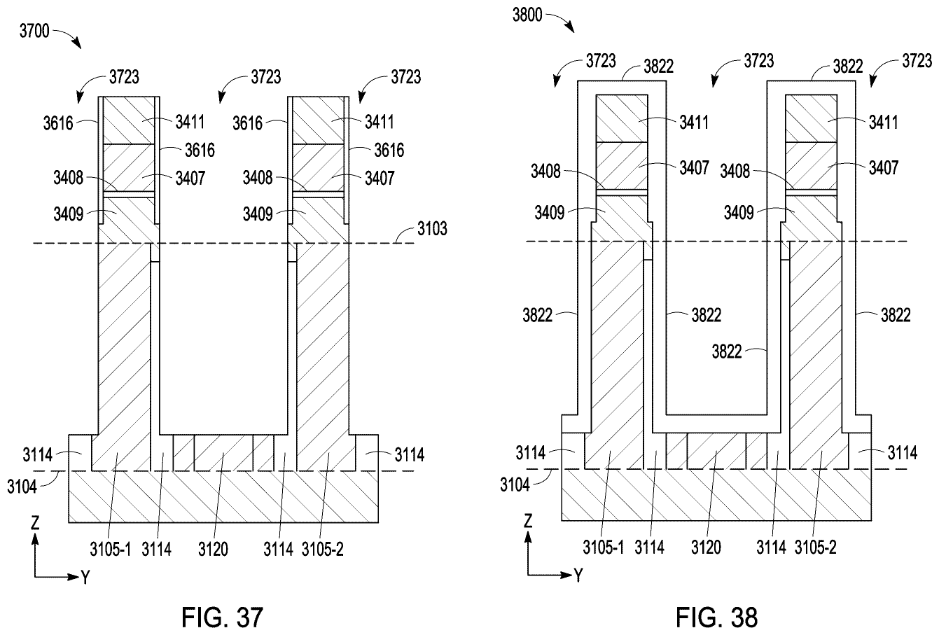

FIG. 37 illustrates a cross-sectional view of a structure 3700, in a DL first formation, after processing structure 3600 of FIG. 36 along the y-direction. A final partial etch has been conducted forming a damascene trench 3723 for a damascene DL. Dielectric region 3511 has been removed. CCON 3105-1, CCON 3105-2, and DL contact 3120 are exposed during the damascene etch.

FIG. 38 illustrates a cross-sectional view of a structure 3800, in a DL first formation, after processing structure 3700 of FIG. 37 along the y-direction. A spacer 3822 has been formed on the surfaces of structure 3700, including walls of damascene trench 3723, tops of on dielectric 3411, and horizontal surfaces extending CCON 3105-1, CCON 3105-2. Spacer 3822, which can include partial liner 3616, can be, but is not limited to, SiO_{X}C_{Y}. A single spacer has been formed with no interfaces. Scaling below 7 nm can be expected without RDF, which is a fail at probe due to leakage across the spacers separating and DL contact 3120 from CCON 3105-1 and CCON 3105-2, where a single spacer can be more suit for processing than a LON scheme. A LON scheme is a spacer scheme of dielectrics closest to the DL, moving out in dielectric formation beginning with a low-k dielectric to an oxide followed by a nitride. A low-k dielectric is a dielectric having a dielectric constant less than silicon dioxide (3.9). The low-k dielectric can be, but is not limited to, SiOC. The oxide can be, but is not limited to, SiO_{X}. The nitride can be, but is not limited to, SiN_{X}. DL capacitance can be lower with an all SiO_{X}C_{Y} spacer and reduced vertical coupling between CCON 3105-1/CCON 3105-2 and DL contact 3120.

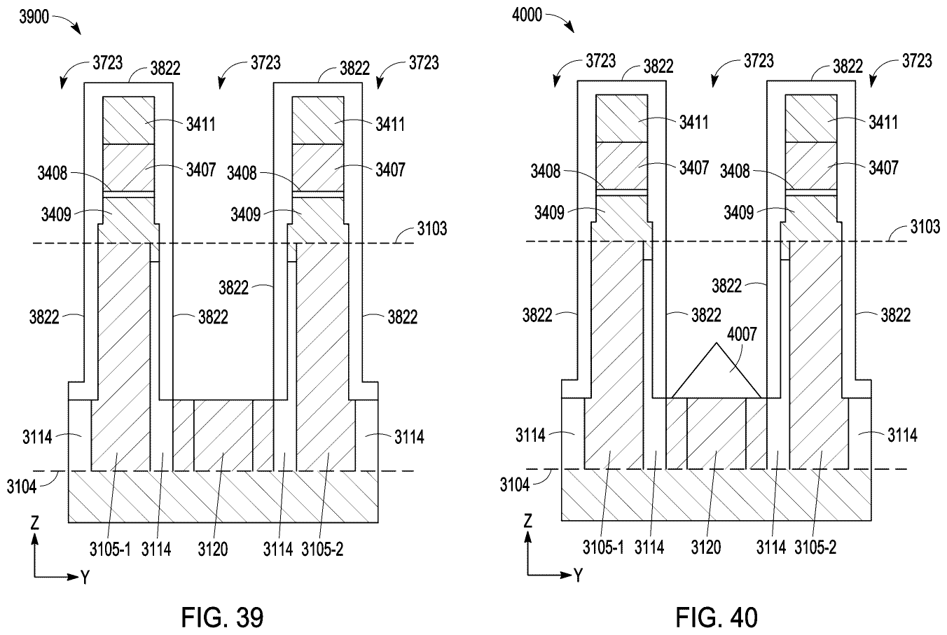

FIG. 39 illustrates a cross-sectional view of a structure 3900, in a DL first formation, after processing structure 3800 of FIG. 38 along the y-direction. A punch has been performed removing the portion of spacer 3822 between CCON 3105-1 and CCON 3105-2, exposing DL contact 3120. Other portions of spacer 3822 remain intact over CCON 3105-1 and CCON 3105-2, removing potential of a short from CCON 3105-1 to DL contact 3120 and from CCON 3105-2 to DL contact 3120.

FIG. 40 illustrates a cross-sectional view of a structure 4000, in a DL first formation, after processing structure 3900 of FIG. 39. An epitaxial silicon 4007 has been form on DL contact 3120.

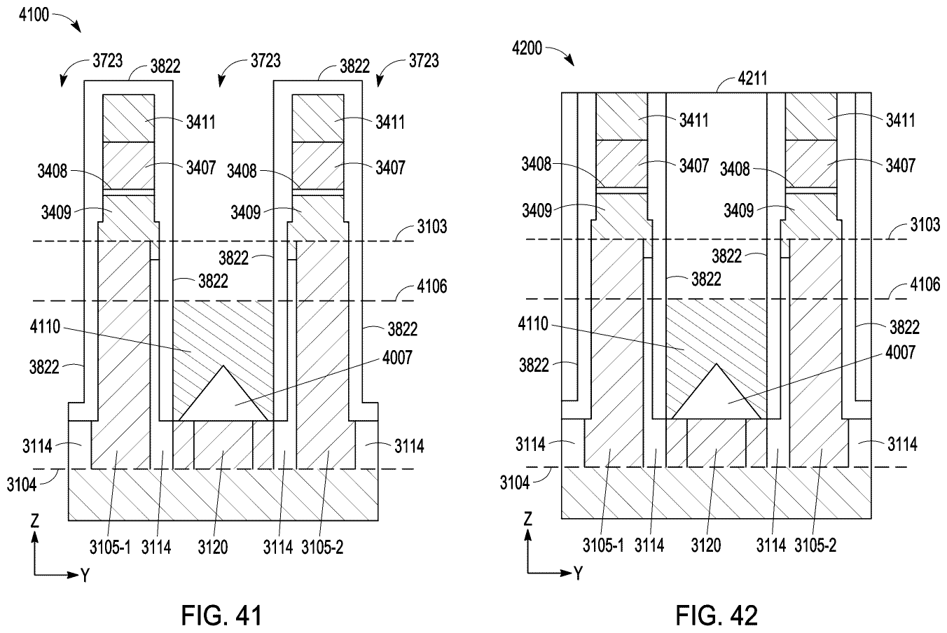

FIG. 41 illustrates across-sectional view of a structure 4100, in a DL first formation, after processing structure 4000 of FIG. 40 in the y-direction. A DL 4110 has been formed on epitaxial silicon 4007 to a top level 4106 for DL 4110. DL 4110 can be a metal with a barrier metal between the metal and epitaxial silicon 4007. Though DL 4110 is formed below CCON surface 3103, DL 4110 can be formed partially buried below CCON surface 3103. Process margin can depend on metal selections to enable DL resistance and minimum spacer thickness specifications.

FIG. 42 illustrates a cross-sectional view of a structure 4200, in a DL first formation, after processing structure 4100 of FIG. 41. Vertical isolation of DL 4110 between CCON surface 3103 has been attained. A dielectric 4211 has been formed on DL 4110. Dielectric 4211 can be a dielectric nitride, such as but not limited to SiN_{X}.

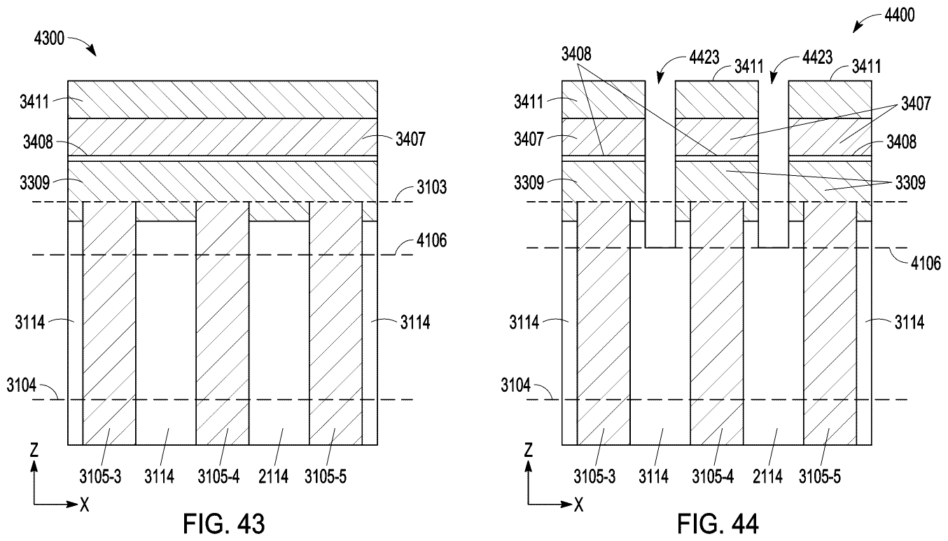

FIG. 43 illustrates a cross-sectional view of a structure 4300, in a DL first formation, that shows structure 4200 of FIG. 42 in the x-direction that includes CCON 505-3, CCON 505-4, and CCON 505-5. FIG. 44 illustrates a cross-sectional view of a structure 4400 in the x-direction, in a DL first formation, after processing structure 4300 of FIG. 43. Conductive connecting of CCON 505-3, CCON 505-4, and CCON 505-5 in the x-direction has been separated by a CCON cut that can be accomplished by a non-selective etch without a self-aligned contact etch. Openings 4423 have been formed by the separation. In addition, a separated contact cap has been formed to each of CCON 505-3, CCON 505-4, and CCON 505-5 separated by openings 4423. Each contact cap formed includes dielectric 3411 on metal 3407 on metal silicide 3408 on polysilicon 3309.

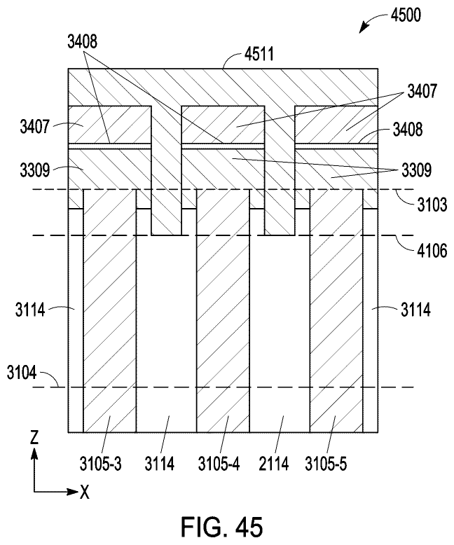

FIG. 45 illustrates a cross-sectional view of a structure 4500, in a DL first formation, after processing structure 4400 of FIG. 44. A dielectric 4511 has been formed on dielectric 3114, filling openings 4423, and an etchback performed. With dielectric 4511 being the same material as dielectric 3411, dielectric 3411 and dielectric 4511 form a continuous dielectric 4511. Dielectric 4511 can be a dielectric nitride, such as but not limited to, SiN_{X}.

Various deposition techniques for components of structures 500-4500 in the process flow of FIGS. 5-45 can be used that are typical for the material being formed, the dimensions of the material being formed, and the architecture in which the material is being formed. Selective etching can be used to remove selected regions in the processing discussed with respect to FIGS. 5-45. Selective etching is a process in which one or more materials are removed from a structure, while one or more other materials remain in the structure with no or little removal. Selective etching can depend on the material to be etched, the material not to be etched, the etchant employed, and the method for etching. Types of etching can include wet etching and dry etching, where each of these two basic methods can include a number of different etching procedures. In addition, conventional masking techniques, providing protective regions in the processing, can be used in removal of selected regions in connecting DLs to DL contacts in the memory array.

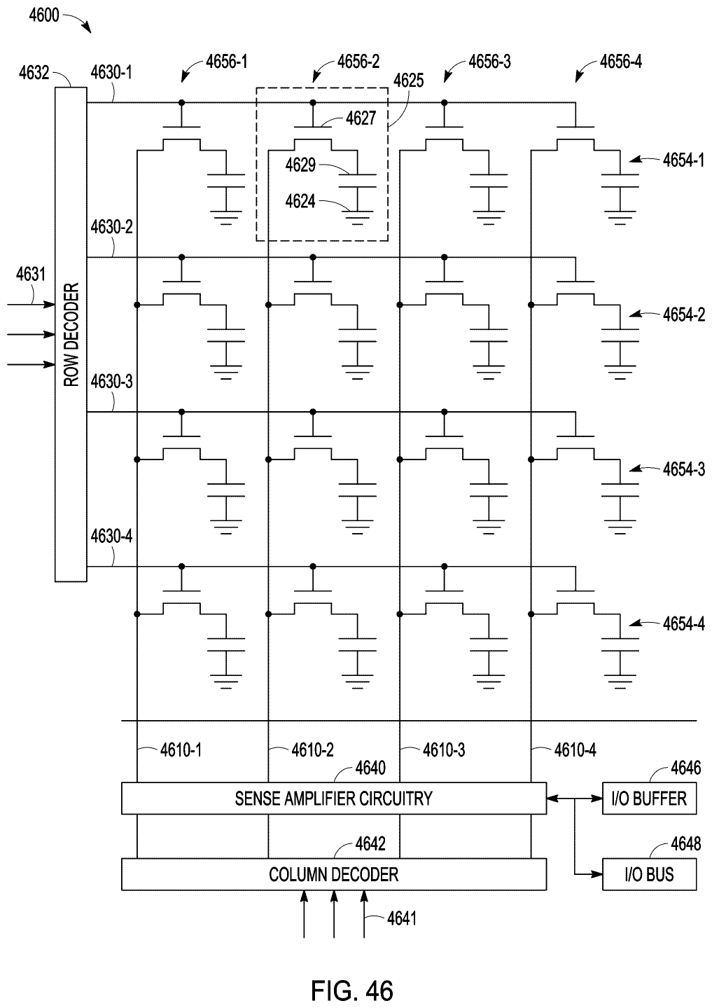

FIG. 46 is a schematic of an embodiment of an example DRAM device 4600 that can include an architecture having DLs at least partially buried below a top surface of CCONs to access transistors and a capacitors of memory cells of a memory array of DRAM device 4600. DRAM device 4600 can include an array of memory cells 4625 (only one being labeled in FIG. 46 for ease of presentation) arranged in rows 4654-1, 4654-2, 4654-3, and 4654-4 and columns 4656-1, 4656-2, 4656-3, and 4656-4. For simplicity and ease of discussion, the array is shown in only two dimensions, but the array can be extended into the third dimension. Further, while only four rows 4654-1, 4654-2, 4654-3, and 4654-4 and four columns 4656-1, 4656-2, 4656-3, and 4656-4 of four memory cells are illustrated, DRAM devices like DRAM device 4600 can have significantly more memory cells 4625 (e.g., tens, hundreds, or thousands of memory cells) per row or per column.

Each memory cell 4625 can include a single transistor 4627 and a single capacitor 4629, which is commonly referred to as a 1T1C (one-transistor-one capacitor cell). One plate of capacitor 4629, which can be termed the “node plate,” is connected to the drain terminal of transistor 4627, whereas the other plate of the capacitor 4629 is connected to a reference 4624, which can be ground. Each capacitor 4629 within the array of 1T1C memory cells 4625 typically serves to store one bit of data, and the respective transistor 4627 serves as an access device to write to or read from storage capacitor 4629.

The transistor gate terminals within each row of rows 4654-1, 4654-2, 4654-3, and 4654-4 are portions of respective WLs 4630-1, 4630-2, 4630-3, and 4630-4 (for example, word lines), and the transistor source terminals within each of columns 4656-1, 4656-2, 4656-3, and 4656-4 are electrically connected to respective DLs 4610-1, 4610-2, 4610-3, and 4610-4 (for example bit lines). A row decoder 4632 can selectively drive the individual WLs 4630-1, 4630-2, 4630-3, and 4630-4, responsive to row address signals 4631 input to row decoder 4632. Driving a given WL at a high voltage causes the access transistors within the respective row to conduct, thereby connecting the storage capacitors within the row to the respective DLs, such that charge can be transferred between the DLs and the storage capacitors for read or write operations. Both read and write operations can be performed via sense amplifier circuitry 4640, which can transfer bit values between the memory cells 4625 of the selected row of the rows 4654-1, 4654-2, 4654-3, and 4654-4 and input/output buffers 4646 (for write/read operations) or external input/output data buses 4648.

A column decoder 4642 responsive to column address signals 4641 can select which of the memory cells 4625 within the selected row is read out or written to. Alternatively, for read operations, the storage capacitors 4629 within the selected row may be read out simultaneously and latched, and the column decoder 4642 can then select which latch bits to connect to the output data bus 4648. Since read-out of the storage capacitors destroys the stored information, the read operation is accompanied by a simultaneous rewrite of the capacitor charge. Further, in between read/write operations, the capacitor charge is repeatedly refreshed to prevent data loss. Details of read/rewrite, write, and refresh operations are well-known to those of ordinary skill in the art.

DLs 4610-1, 4610-2, 4610-3, and 4610-4 can be constructed as metal DLs in a process flow to form the metal DLs buried below top surfaces of CCONs, as taught herein. The metal can be the same for DLs 4610-1, 4610-2, 4610-3, and 4610-4 and the metal contacts to these DLs and can be formed at the same time in the fabrication process flow.

DRAM device 4600 may be implemented as an integrated circuit within a package that includes pins for receiving supply voltages (e.g., to provide the source and gate voltages for the transistors 4627) and signals (including data, address, and control signals). FIG. 46 depicts DRAM device 4600 in simplified form to illustrate basic structural components, omitting many details of the memory cells 4625 and associated WLs 4630-1, 4630-2, 4630-3, and 4630-4 and DLs 4610-1, 4610-2, 4610-3, and 4610-4 as well as the peripheral circuitry. For example, in addition to the row decoder 4632 and column decoder 4642, sense amplifier circuitry 4640, and buffers 4646, DRAM device 4600 may include further peripheral circuitry, such as a memory control unit that controls the memory operations based on control signals (provided, e.g., by an external processor), additional input/output circuitry, etc. Details of such peripheral circuitry are generally known to those of ordinary skill in the art and not further discussed herein.

Electronic devices can be broken down into several main components: a processor (e.g., a central processing unit (CPU) or other main processor); memory (e.g., one or more volatile or non-volatile RAM memory device, such as DRAM, mobile or low-power double-data-rate synchronous DRAM (DDR SDRAM), etc.); and a storage device (e.g., non-volatile memory (NVM) device, such as flash memory, ROM, a solid-state drive (SSD), a MultiMediaCard (MMC), or other memory card structure or assembly, etc.). Electronic devices, such as mobile electronic devices (e.g., smart phones, tablets, etc.), electronic devices for use in automotive applications (e.g., automotive sensors, control units, driver-assistance systems, passenger safety or comfort systems, etc.), and internet-connected appliances or devices (e.g., Internet-of-Things (IoT) devices, etc.), have varying storage needs depending on, among other things, the type of electronic device, use environment, performance expectations, etc. In certain examples, electronic devices can include a user interface (e.g., a display, touch-screen, keyboard, one or more buttons, etc.), a graphics processing unit (GPU), a power management circuit, a baseband processor or one or more transceiver circuits, etc. As used herein, “processor device” means any type of computational circuit such as, but not limited to, a microprocessor, a microcontroller, a graphics processor, a digital signal processor (DSP), or any other type of processor or processing circuit, including a group of processors or multi-core devices.

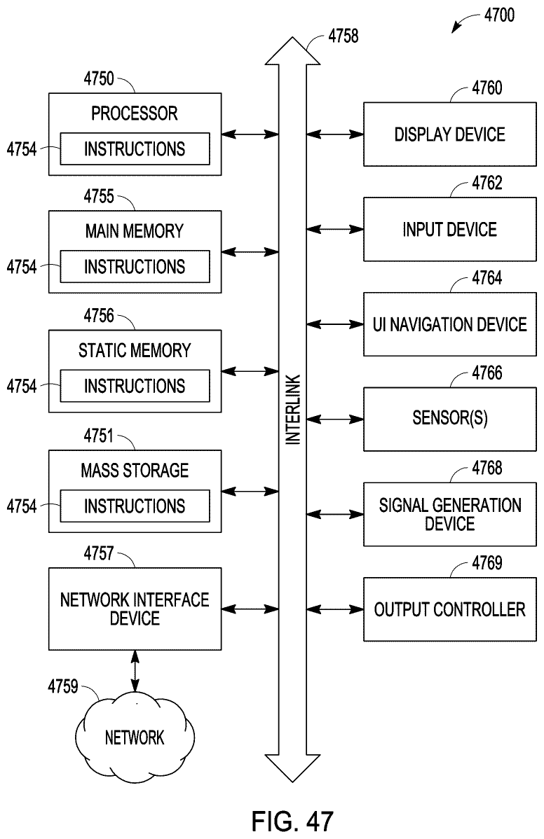

FIG. 47 illustrates a block diagram of an example machine 4700 having one or more embodiments of memory components discussed herein. In alternative embodiments, machine 4700 may operate as a standalone device or may be connected (e.g., networked) to other machines. In a networked deployment, machine 4700 may operate in the capacity of a server machine, a client machine, or both in server-client network environments. In an example, machine 4700 may act as a peer machine in peer-to-peer (P2P) (or other distributed) network environment. Machine 4700 may be a personal computer (PC), a tablet PC, a set-top box (STB), a personal digital assistant (PDA), a mobile telephone, a web appliance, an IoT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform one or more of methodologies such as, but not limited to, cloud computing, software as a service (SaaS), or other computer cluster configurations. Example machine 4700 can include one or more memory devices having structures as discussed with respect to structure 100 of FIG. 1.

Machine (e.g., computer system) 4700 may include a hardware processor 4750 (e.g., a CPU, a GPU, a hardware processor core, or any combination thereof), a main memory 4755 and a static memory 4756, some or all of which may communicate with each other via an interlink (e.g., bus) 4758. Machine 4700 may further include a display device 4760, an alphanumeric input device 4762 (e.g., a keyboard), and a user interface (UI) navigation device 4764 (e.g., a mouse). In an example, display device 4760, alphanumeric input device 4762, and UI navigation device 4764 may be a touch screen display. Machine 4700 may additionally include a mass storage (e.g., drive unit) 4751, a signal generation device 4768 (e.g., a speaker), a network interface device 4757, and one or more sensors 4766, such as a global positioning system (GPS) sensor, compass, accelerometer, or other sensor. Machine 4700 may include an output controller 4769, such as a serial (e.g., USB, parallel, or other wired or wireless (e.g., infrared (IR), near field communication (NFC), etc.) connection to communicate or control one or more peripheral devices (e.g., a printer, card reader, etc.).

Machine 4700 may include a machine-readable medium on which is stored one or more sets of data structures or instructions 4754 (for example, software or microcode) embodying or utilized by machine 4700. Instructions 4754 may also reside, completely or at least partially, within main memory 4755, within static memory 4756, within mass storage 4751, or within hardware processor 4750 during execution thereof by machine 4700. In an example, one or any combination of hardware processor 4750, main memory 4755, static memory 4756, or mass storage 4751 may constitute machine-readable medium. Machine-readable medium can be a single medium or multiple media (e.g., a centralized or distributed database, or associated caches and servers) configured to store one or more instructions 4754.

The term “machine-readable medium” may include any medium that is capable of storing instructions for execution by machine 4700 and that cause machine 4700 to perform any one or more of the techniques for which machine 4700 is implemented. Non-limiting machine-readable medium examples may include solid-state memories, and optical and magnetic media. Non-volatile machine-readable medium may include semiconductor memory devices such as EPROM, EEPROM, and flash memory devices; magnetic disks, such as internal hard disks and removable disks; magneto-optical disks; and compact disc-ROM (CD-ROM) and digital versatile disc-read only memory (DVD-ROM) disks. Volatile machine-readable medium may include (RAM), DRAM, SRAM, or SDRAM.

Instructions 4754 (e.g., software, programs, microcode, an operating system (OS), etc.) or other data stored on mass storage 4751, can be accessed by main memory 4755 for use by processor 4750. Main memory 4755 (e.g., DRAM) is typically fast, but volatile, and thus a different type of storage than mass storage 4751 (e.g., an SSD), which is suitable for long-term storage, including while in an “off” condition. Instructions 4754 or data in use by a user or machine 4700 are typically loaded in main memory 4755 for use by processor 4750. When main memory 4755 is full, virtual space from mass storage 4751 can be allocated to supplement main memory 4755; however, because mass storage 4751 is typically slower than main memory 4755, and write speeds are typically at least twice as slow as read speeds, use of virtual memory can greatly reduce user experience due to storage device latency (in contrast to main memory 4755, e.g., DRAM). Further, use of mass storage 4751 for virtual memory can greatly reduce the usable lifespan of mass storage 4751.

Storage devices optimized for mobile electronic devices, or mobile storage, traditionally include MMC solid-state storage devices (e.g., micro Secure Digital (microSD™) cards, etc.). MMC devices include a number of parallel interfaces (e.g., an 8-bit parallel interface) with a host device and are often removable and separate components from the host device. In contrast, eMMC™ devices are attached to a circuit board and considered a component of the host device, with read speeds that rival SATA based SSD devices. However, demand for mobile device performance continues to increase, such as to fully enable virtual or augmented-reality devices, utilize increasing networks speeds, etc. In response to this demand, storage devices have shifted from parallel to serial communication interfaces. UFS devices, including controllers and firmware, communicate with a host device using a low-voltage differential signaling (LVDS) serial interface with dedicated read/write paths, further advancing greater read/write speeds.

Instructions 4754 may further be transmitted or received over a network 4759 using a transmission medium via network interface device 4757 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, peer-to-peer (P2P) networks, among others. In an example, network interface device 4757 may include one or more physical jacks (e.g., Ethernet, coaxial, or phone jacks) or one or more antennas to connect to the communications network 4726. In an example, network interface device 4757 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any tangible medium that is capable of transporting instructions for execution by machine 4700 or data to or from machine 4700. The transportation can include using digital or analog communications signals that can be transmitted over the transmission medium to facilitate communication of such software or data.

The following are example embodiments of devices and methods, in accordance with the teachings herein.

An example memory device 1 can comprise an array of memory cells, a memory cell of the array including an access transistor in a substrate below a surface of the substrate with the access transistor coupled to a capacitor, a WL coupled to the access transistor, and a DL coupled to the access transistor, the DL at least partially buried below a top surface of substrate cell contacts to the access transistor and the capacitor, the top surface of the substrate cell contacts located at the surface of the substrate.

An example memory device 2 can include features of example memory device 1 and can include the memory cells arranged in a 6F² architecture.

An example memory device 3 can include features of any of the preceding example memory devices and can include a contact cap positioned on and contacting one of the substrate cell contacts, coupling the one substrate cell contact to a RDL, the contact cap including a barrier metal on a polysilicon region that is on and contacting the one substrate cell contact.

An example memory device 4 can include features of any of the preceding example memory devices and can include the substrate for the memory cells being a silicon substrate.

An example memory device 5 can include features of any of the preceding example memory devices and can include the DL being completely buried below the top surface of the substrate cell contacts.

An example memory device 6 can include features of any of the preceding example memory devices and can include a barrier metal being included in the coupling of the DL to a DL contact to the access transistor.

An example memory device 7 can include features of example memory device 6 and any of the preceding example memory devices and can include a polysilicon region located between the barrier metal and the DL contact.

An example memory device 8 can include features of example memory device 6 and any of the preceding example memory devices and can include the barrier metal to include one or more of titanium, titanium nitride, tungsten nitride, tungsten silicide, or tungsten silicide nitride.

An example memory device 9 can include features of any of the preceding example memory devices and can include the DL to include one or more of tungsten, titanium tungsten, or molybdenum.

An example memory device 10 can include features of any of the preceding example memory devices and can include the DL being recessed having a recess depth to the top surface of substrate cell contacts, the recess depth providing an optimization of parasitic DL capacitance versus access device performance.

In an example memory device 11, any of the memory devices of example memory devices 1 to 10 may include memory devices incorporated into an electronic apparatus further comprising a host processor or memory controller and a communication bus extending between the host processor/memory controller and the memory device.

In an example memory device 12, any of the memory devices of example memory devices 1 to 11 may be modified to include any structure presented in another of example memory device 1 to 11.

In an example memory device 13, any apparatus associated with the memory devices of example memory devices 1 to 12 may further include a machine-readable storage device configured to store instructions as a physical state, wherein the instructions may be used to perform one or more operations of the apparatus.

In an example memory device 14, any of the memory devices of example memory devices 1 to 13 may be operated in accordance with any of the below example methods 1 to 11 and methods 12 to 16.

An example method 1 of forming a memory device can comprise forming an array of access transistors for memory cells in a substrate below a surface of the substrate, an access transistor of the array to couple to a capacitor forming a memory cell; forming a WL coupled to the access transistor; and forming a DL coupled to the access transistor, including forming the DL at least partially buried below a top surface of substrate cell contacts to the access transistor and the capacitor, the top surface of the substrate cell contacts at the surface of the substrate.

An example method 2 of forming a memory device can include features of example method 1 of forming a memory device and can include forming the array of memory cells to include forming the memory cells arranged in a 6F² architecture.

An example method 3 of forming a memory device can include features of any of the preceding example methods of forming a memory device and can include forming the DL to include completely burying the DL below the top surface of the substrate cell contacts.

An example method 4 of forming a memory device can include features of any of the preceding example methods of forming a memory device and can include in a first processing direction, forming the substrate cell contacts and a DL contact to the access transistor electrically separated from each other; and in a second processing direction, after forming the substrate cell contacts and the DL contact electrically separated from each other, forming the DL coupled to the DL contact in a damascene trench.

An example method 5 of forming a memory device can include features of example method 4 of forming a memory device and any of the preceding example methods of forming a memory device and can include in a first processing direction, forming, in a damascene trench, the DL coupled to a DL contact to the access transistor; and in a second processing direction, after forming the DL coupled to a DL contact, forming the substrate cell contacts and the DL contact electrically separated from each other.

In an example method 6, any of the example methods 1 to 5 of forming a memory device may be performed in forming an electronic apparatus further comprising a host processor and a communication bus extending between the host processor and a memory system.

In an example method 7 of forming a memory device, any of the example methods 1 to 6 of forming a memory device may be modified to include operations set forth in any other of example methods 1 to 6.

In an example method 8 of forming a memory device, any of the example methods 1 to 7 of forming a memory device may be implemented at least in part through use of instructions stored as a physical state in one or more machine-readable storage devices.

An example method 9 of forming a memory device can include features of any of the preceding example methods 1 to 8 of forming a memory device and can include performing functions associated with any features of example memory devices 1 to 14.

An example method 10 of forming a memory device can comprise forming an array of access transistors for memory cells in a substrate below a surface of the substrate, an access transistor of the array to couple to a capacitor forming a memory cell; forming substrate cell contacts and a DL contact to the access transistor; forming polysilicon in a blank formation on the substrate cell contacts, the DL contact, and regions between the substrate cell contacts and the DL contact; in a first direction, removing portions of the polysilicon and filling openings, formed by removing the portions, with dielectric material; in a second direction, forming a trench in the polysilicon to a level providing a remaining portion of the polysilicon such that an opening is provided above the remaining portion above the DL contact; extending the trench through the remaining portion and recessing the DL contact; and forming a DL in the extended trench, with the DL at least partially buried below a top surface of the substrate cell contacts, the top surface of the substrate cell contacts at the surface of the substrate.

An example method 11 of forming a memory device can include features of example method 10 of forming a memory device and can include forming, above the polysilicon, material for contact caps to the substrate cell contacts; in the first direction, removing portions of the material for contact caps when removing portions of the polysilicon, electrically separating contact caps to the substrate cell contacts from each other, and in the second direction, forming the trench through the material for contact caps when forming the trench in the polysilicon.

An example method 12 of forming a memory device can include features of example method 11 of forming a memory device and any of the preceding example method 10 of forming a memory device and can include forming material for contact caps to include forming a metal region on a metal barrier contacting the polysilicon.

An example method 13 of forming a memory device can include features of any of the preceding example methods of forming a memory device and can include forming a protective liner on walls of the trench extending the trench through the remaining portion and recessing the DL contact.

An example method 14 of forming a memory device can include features of any of the preceding example methods 10 to 13 of forming a memory device and can include adjusting a recess depth of the DL from the top surface of the substrate cell contacts to provide a desired status of parasitic DL capacitance versus access device performance.

In an example method 15 of forming a memory device, any of the example methods 10 to 14 of forming a memory device may be performed in forming an electronic apparatus further comprising a host processor and a communication bus extending between the host processor and a memory system.

In an example method 16 of forming a memory device, any of the example methods 10 to 15 of forming a memory device may be modified to include operations set forth in any other of example methods 10 to 15 of forming a memory device.

In an example method 17 of forming a memory device, any of the example methods 10 to 16 of forming a memory device may be implemented at least in part through use of instructions stored as a physical state in one or more machine-readable storage devices.

An example method 18 of forming a memory device can include features of any of the preceding example methods 10 to 17 of forming a memory device and can include performing functions associated with any features of example memory devices 1 to 14.

An example machine-readable storage device storing instructions, that when executed by one or more processors, cause a machine to perform operations, can comprise instructions to perform functions associated with any features of example memory devices 1 to 14 or perform form methods associated with any features of example methods 1 to 9 of forming a memory device or example methods 10 to 18 of forming a memory device.

Although specific embodiments have been illustrated and described herein, it will be appreciated by those of ordinary skill in the art that any arrangement that is calculated to achieve the same purpose may be substituted for the specific embodiments shown. Various embodiments use permutations and/or combinations of embodiments described herein. It is to be understood that the above description is intended to be illustrative, and not restrictive, and that the phraseology or terminology employed herein is for the purpose of description.

What is claimed is:

1. A memory device comprising:
an array of memory cells, a memory cell of the array including an access transistor in a substrate below a surface of the substrate with the access transistor coupled to a capacitor;
an access line coupled to the access transistor; and
a digit line coupled to the access transistor, the digit line at least partially buried below a top surface of substrate cell contacts to the access transistor and the capacitor, the top surface of the substrate cell contacts located at the surface of the substrate.

2. The memory device of claim 1, wherein the memory cells are arranged in a 6F² architecture.

3. The memory device of claim 1, wherein a contact cap is positioned on and contacting one of the substrate cell contacts, coupling the one substrate cell contact to a redistribution layer, the contact cap including a barrier metal on a polysilicon region that is on and contacting the one substrate cell contact.

4. The memory device of claim 1, wherein the substrate for the memory cells is a silicon substrate.

5. The memory device of claim 1, wherein the digit line is completely buried below the top surface of the substrate cell contacts.

6. The memory device of claim 1, wherein a barrier metal is included in the coupling of the digit line to a digit line contact to the access transistor.

7. The memory device of claim 6, wherein a polysilicon region is located between the barrier metal and the digit line contact.

8. The memory device of claim 6, wherein the barrier metal includes one or more of titanium, titanium nitride, tungsten nitride, tungsten silicide, or tungsten silicide nitride.

9. The memory device of claim 1, wherein the digit line includes one or more of tungsten, titanium tungsten, or molybdenum.

10. The memory device of claim 1, wherein the digit line is recessed having a recess depth to the top surface of substrate cell contacts, the recess depth providing an optimization of parasitic digit line capacitance versus access device performance.

11. A method of forming a memory device comprising:
forming an array of access transistors for memory cells in a substrate below a surface of the substrate, an access transistor of the array to couple to a capacitor forming a memory cell;
forming an access line coupled to the access transistor; and
forming a digit line coupled to the access transistor, including forming the digit line at least partially buried below a top surface of substrate cell contacts to the access transistor and the capacitor, the top surface of the substrate cell contacts at the surface of the substrate.

12. The method of claim 11, wherein forming the array of memory cells includes forming the memory cells arranged in a 6F² architecture.

13. The method of claim 11, wherein forming the digit line includes completely burying the digit line below the top surface of the substrate cell contacts.

14. The method of claim 11, wherein the method includes:
in a first processing direction, forming the substrate cell contacts and a digit line contact to the access transistor electrically separated from each other; and
in a second processing direction, after forming the substrate cell contacts and the digit line contact electrically separated from each other, forming the digit line coupled to the digit line contact in a damascene trench.

15. The method of claim 11, wherein the method includes:
in a first processing direction, forming, in a damascene trench, the digit line coupled to a digit line contact to the access transistor; and
in a second processing direction, after forming the digit line coupled to a digit line contact, forming the substrate cell contacts and the digit line contact electrically separated from each other.

16. A method of forming a memory device comprising:
forming an array of access transistors for memory cells in a substrate below a surface of the substrate, an access transistor of the array to couple to a capacitor forming a memory cell;
forming substrate cell contacts and a digit line contact to the access transistor;
forming polysilicon in a blank formation on the substrate cell contacts, the digit line contact, and regions between the substrate cell contacts and the digit line contact;
in a first direction, removing portions of the polysilicon and filling openings, formed by removing the portions, with dielectric material;
in a second direction, forming a trench in the polysilicon to a level providing a remaining portion of the polysilicon such that an opening is provided above the remaining portion above the digit line contact;
extending the trench through the remaining portion and recessing the digit line contact;
and
forming a digit line in the extended trench, with the digit line at least partially buried below a top surface of the substrate cell contacts, the top surface of the substrate cell contacts at the surface of the substrate.

17. The method of claim 16, wherein the method includes:
forming, above the polysilicon, material for contact caps to the substrate cell contacts;
in the first direction, removing portions of the material for contact caps when removing portions of the polysilicon, electrically separating contact caps to the substrate cell contacts from each other; and
in the second direction, forming the trench through the material for contact caps when forming the trench in the polysilicon.

18. The method of claim 17, wherein forming material for contact caps includes forming a metal region on a metal barrier contacting the polysilicon.

19. The method of claim 16, wherein the method includes forming a protective liner on walls of the trench extending the trench through the remaining portion and recessing the digit line contact.

20. The method of claim 16, wherein the method includes adjusting a recess depth of the digit line from the top surface of the substrate cell contacts to provide a desired status of parasitic digit line capacitance versus access device performance.
